(19) United States
(12) Patent Application Publication
(10) Pub. No.: US 2026/0320271 A1
(43) Pub. Date: Oct. 15, 2026

(54) COMPUTING SYSTEMS AND METHODS FOR CIRCUIT SIMULATION AND DESIGN USING NEURAL NETWORK MODELS

(71) Applicant: ASTERQUANTA SOLUTIONS INC., Stittsville (CA)

(72) Inventors: Pradeep VSR PYDAH, Stittsville (CA); Rajesh Seshadri IYENGAR, Bangalore (IN); Neerava NAGARAJ, Bangalore (IN); Ishaan HEGDE, Sagar (IN); Ravikanth RACHAPUTI, Hyderabad (IN); Mohammad Hossein SARFI, Calgary (CA)

(21) Appl. No.: 19/646,037

(22) Filed: Apr. 13, 2026

Related U.S. Application Data
(60) Provisional application No. 63/788,995, filed on Apr. 15, 2025.

(51) Int. Cl. G06F 30/3308; G06F 30/27; G06F 30/39

(52) U.S. Cl. CPC G06F 30/3308; G06F 30/27; G06F 30/39

(57) ABSTRACT

A computing system is provided for simulating and automatically modifying or create (or both) electrical circuits to improve performance specifications, using artificial intelligence and a closed-loop architecture. The computing system integrates multiple dynamically generated reinforcement learning environments and deep neural networks, including a graph convolutional neural network with reinforcement learning, to facilitate optimization of circuits. In some cases, the computing system provides a user interface for displaying circuits and performance data, and for controlling access to third parties to use the circuits.

### CROSS-REFERENCE TO RELATED APPLICATION

This patent application claims priority to United States Provisional Patent Application No. 63/788,995 filed on Apr. 15, 2025, and tilted “COMPUTING SYSTEMS AND METHODS FOR CIRCUIT SIMULATION AND DESIGN USING NEURAL NETWORK MODELS”, the entire contents of which are hereby incorporated by reference.

### TECHNICAL FIELD

The disclosed exemplary embodiments relate to computing systems and methods for circuit simulation and design using neural network models, including simulating and designing electronic systems and semiconductors.

### BACKGROUND

### Semiconductor Integrated Circuits and Electronic Systems are Currently Designed Using Electronic Design Automation (EDA)

Electronic Design Automation (EDA) refers to a category of software tools used in the design of electronic systems such as integrated circuits and printed circuit boards. The tools work by automating lengthy and complex design processes that would be virtually impossible to perform manually with the same level of accuracy or efficiency. EDA tools are essential for many electrical engineers and designers, enabling them to create and simulate semiconductor chips, lay out Printed Circuit Boards (PCBs), and verify designs before manufacturing, thereby reducing errors and speeding up the design-to-production process.

The core functions of EDA software include schematic capture (e.g., for creating the circuit diagram), simulation (e.g., to test and validate the functionality of circuits), layout generation (e.g., for physical realization of the circuit design), and manufacturing preparation (e.g., preparing design data for fabrication). Major EDA software providers include companies like Synopsys, Cadence, and Mentor Graphics, which offer specialized tools that support various aspects of semiconductor and PCB design. 2 EDA tools are often used in developing technology for a range of applications, from consumer electronics and automotive systems to telecommunications and industrial machinery, as they help streamline the development process for advanced technologies.

### SUMMARY

The following summary is intended to introduce the reader to various aspects of the detailed description, but not to define or delimit any invention.

In at least one broad aspect, a computing system is provided via a network (e.g., the Internet) for semiconductor and electronic system designers. In some cases, the computing system is a web-based platform that includes artificial intelligence (AI) models to simulate semiconductor and/or hardware design, and to collaborate with inputs provided by a data account (e.g., a user account). In some cases, the computing system facilitates multiple data accounts controllable by uses from two different domains (e.g., semiconductor domain and AI domain) to work together on projects from anywhere in the world. In some cases, the computing system includes a distributed control system enabling the simultaneous simulation and co-development of designs across the computing system. In some cases, the computing system is configured to translates circuit, semiconductor and electronic system domain and design requirements to specifications that are readable and processed by an AI model for the computing system.

In at least one broad aspect, a computing system is provided that includes data connectors to provide a network-accessed simulation platform for circuit and system design.

In some cases, the computing system provides a user interface to select simulation tools and run simulations.

In some cases, the computing system collects simulation environment data.

In some cases, the computing system provides a user interface to control simulation and design parameters.

In some cases, the computing system is a platform-as-a-service to AI developers.

In some cases, the computing system comprises a user interface with controls to connect AI models to EDA tools (e.g., simulation environments).

In some cases, the computing system receives simulation outputs from EDA tools (e.g., simulation environments).

In some cases, the computing system includes a user interface that controls simulation and design parameters in EDA tools.

In some cases, the computing system automatically switches between multiple AI models and connects to multiple EDA tools and simulation environments. In some cases, the computing system provides a user interface with controls to selectively switch between AI models and connect to one or more EDA tools and simulation environments.

In some cases, the computing system includes nested and orchestrated AI algorithms and controls. In some cases, the computing system includes nested cost functions in AI algorithms.

In some cases, the computing system controls execution of one or more AI algorithms.

In at least another broad aspect, a computing system for automatically modifying an electrical circuit is provided. The computing system comprising: a memory storing instructions; and a processor operatively coupled to the memory, the processor configured by the instructions to: execute an iterative optimization process loop, the process loop comprising: (a) causing a simulation environment to simulate the electrical circuit using a current set of one or more controllable parameters to generate a corresponding set of performance metrics; (b) providing the set of performance metrics to an artificial intelligence (AI) agent, wherein the AI agent is configured to process a topological representation of the electrical circuit; (c) receiving, from the AI agent, a new set of the one or more controllable parameters, wherein the new set is generated by the AI agent based on the set of performance metrics and one or more target specification values; and (d) repeating steps (a) through (c) using the new set as the current set of the one or more controllable parameters for a subsequent iteration.

In some cases, the topological representation comprises a graph representation, wherein components of the electrical circuit correspond to nodes of the graph representation and connections between the components correspond to edges of the graph representation.

In some cases, the AI agent comprises a graph convolutional neural network (GCN) configured to process the graph representation.

In some cases, the AI agent is configured with a reinforcement learning (RL) framework to generate the new set of the one or more controllable parameters.

In some cases, the RL framework comprises an actor-critic architecture.

In some cases, the processor is further configured to generate the topological representation by at least: ingesting an image of a circuit diagram; using image recognition to extract a plurality of components and a plurality of connections that form the circuit diagram; and, generating a data file that comprises the topological representation, the data file processed by the AI agent.

In some cases, the process loop is repeated until a stop condition is detected, the stop condition comprising at least one of: a determination that the set of performance metrics meets or exceeds the one or more target specification values, or a determination that a series of consecutive sets of performance metrics has reached a steady state.

In some cases, the processor is further configured to display, via a graphical user interface, a visualization of the performance metrics generated during each iteration of the process loop.

In at least another broad aspect, a computing system is provided for automatically modifying an electrical circuit, the computing system comprising a memory, a communication interface, and a processor operatively coupled to the memory and the communication interface. The processor is configured to at least: obtain a data file representing the electrical circuit; obtain one or more controllable parameters of the electrical circuit and one or more target specification values of the electrical circuit; initiate a process loop comprising inputting the data file and an initial value set of the one or more controllable parameters into a simulation environment and obtain, from the simulation environment, an initial set of specification values resulting from simulating the electrical circuit. The processor is further configured to execute the process loop comprising: input the data file, the initial set of specification values, and the one or more target specification values into an artificial intelligence (AI) agent, comprising a graph convolutional neural network with reinforcement learning, to obtain a new value set of the one or more controllable parameters; and feedback the new value set of the one or more controllable 8 parameters into the simulation environment, to continue the process loop, comprising generating another set of specification values resulting from simulating the electrical circuit using the new value set of the one or more controllable parameters, wherein the another set of specification values are inputted into the AI agent. The processor is further configured to repeat the process loop of the simulation environment and the AI agent, until a stop condition has been detected.

In some cases, the computing system comprises an AI electrical simulation platform, the simulation environment and the AI agent; and wherein, the AI electrical simulation platform communicates with the simulation environment and with the AI agent via respective data connectors.

In some cases, the processor is configured to obtain the electrical circuit by at least: ingesting an image of a circuit diagram; using image recognition to extract a plurality of components and a plurality of connections that form the circuit diagram; and, generate the digital file that comprises the plurality of components and the plurality of connections to represent the circuit diagram.

In some cases, the digital file comprises a graph representation comprising a plurality of nodes representing the plurality of components.

In some cases, the processor is configured to display a graphical user interface that comprises a series of sets of specification values outputted by the simulation environment in real-time corresponding to each iteration of the process loop.

In some cases, the stop condition comprises a given iteration of a set of specification values matches or exceeds the one or more target specification values.

In some cases, the stop condition comprises a series of consecutive sets of specification values has reached a steady state.

In at least another broad aspect, a computing system is provided for automatically modifying an electrical circuit, the computing system comprising: a memory storing instructions; and a processor operatively coupled to the memory. The processor is configured by the instructions to: obtain a data file representing the electrical circuit, one or more controllable parameters of the electrical circuit, and one or more target specification values for the electrical circuit; and initiate and execute a process loop. The process loop comprising: (a) inputting a current value set of the one or more controllable parameters into a simulation environment to generate a current set of specification values for the electrical circuit; (b) inputting the data file, the current set of specification values, and the one or more target specification values into an artificial intelligence (AI) agent, wherein the AI agent comprises a graph convolutional neural network (GCN) configured with a reinforcement learning (RL) framework; (c) obtaining, from the AI agent, a new value set of the one or more controllable parameters generated based on a policy of the RL framework; and (d) providing the new value set as the current value set for a subsequent iteration of the process loop. The processor is further configured to repeat the process loop until a stop condition is detected.

In some cases, the data file representing the electrical circuit comprises a graph representation, wherein components of the electrical circuit correspond to nodes of the graph representation and connections between the components correspond to edges of the graph representation.

In some cases, the processor is configured to obtain the data file by: ingesting an image of a circuit diagram for the electrical circuit; applying an image recognition process to extract a plurality of components and a plurality of connections from the circuit diagram; and generating the data file based on the extracted plurality of components and plurality of connections.

In some cases, the AI agent comprises an actor-critic architecture.

In some cases, the stop condition comprises a determination that a current set of specification values meets or exceeds the one or more target specification values.

In some cases, the stop condition comprises a determination that a series of consecutive sets of specification values has reached a steady state.

In some cases, the processor is further configured to display, via a graphical user interface, a visualization of the specification values generated during each iteration of the process loop.

In an at least another broad aspect, an artificial intelligence-based system is provided for optimizing a circuit design, the system comprising: a physics extraction module configured to obtain operating point data for a plurality of components of a circuit from a circuit simulator; a graph processing layer configured to process a graph representation of the circuit to generate a graph-level output, wherein nodes of the graph representation correspond to the plurality of components and are associated with feature 11 vectors comprising the operating point data; a metric processing network configured to process performance metric data associated with the circuit to generate a metric-level output; a fusion operator configured to combine the graph-level output and the metric-level output to produce a joint observation representation; and a policy network configured to process the joint observation representation to generate an action vector corresponding to an optimization for the circuit design.

In some cases, the graph processing layer comprises one or more graph convolutional network (GCN) layers configured to propagate information across a topology of the circuit.

In some cases, the feature vectors associated with the nodes of the graph representation further comprise component-type information and physical property information for the plurality of components.

In some cases, the artificial intelligence-based system further comprises a projection stage configured to convert the graph-level output into a fixed-dimension vector before the graph-level output is combined by the fusion operator.

In some cases, the artificial intelligence-based system is configured to update the feature vectors with new operating point data obtained by the physics extraction module after each simulation of the circuit.

In some cases, the operating point data is normalized based on a data-driven calibration procedure.

In at least another broad aspect, a computer-implemented method is provided for optimizing a circuit design, the method comprising: obtaining, via a physics extraction module, operating point data for a plurality of components of a circuit from a circuit simulator; processing, via a graph processing layer, a graph representation of the circuit to generate a graph-level output, wherein nodes of the graph representation correspond to the plurality of components and are associated with feature vectors comprising the operating point data; processing, via a metric processing network, performance metric data associated with the circuit to generate a metric-level output; combining, via a fusion operator, the graph-level output and the metric-level output to produce a joint observation representation; and processing, via a policy network, the joint observation representation to generate an action vector corresponding to an optimization for the circuit design.

In some cases, processing the graph representation is performed by one or more graph convolutional network (GCN) layers that propagate information across a topology of the circuit.

In some cases, the feature vectors associated with the nodes of the graph representation further comprise component-type information and physical property information for the plurality of components.

In some cases, the computer-implemented method further comprises converting the graph-level output into a fixed-dimension vector prior to the combining step.

In some cases, the computer-implemented method further comprises updating the feature vectors with new operating point data after each simulation of the circuit.

In some cases, the computer-implemented method further comprises normalizing the operating point data based on a data-driven calibration procedure performed prior to processing the graph representation.

In at least another broad aspect, an artificial intelligence-based system is provided for optimizing a design of an electrical circuit, the system comprising: a memory storing instructions; and a processor operatively coupled to the memory, the processor configured by the instructions to implement: a physics extraction module configured to obtain, from a circuit simulator, operating point data for a plurality of components of the electrical circuit, the operating point data representing internal electro-physical quantities of the plurality of components during a simulation; a graph processing layer configured to process a graph representation of the electrical circuit to generate a graph-level output, wherein nodes of the graph representation correspond to the plurality of components and are associated with feature vectors comprising the operating point data; a metric processing network configured to process performance metric data associated with the electrical circuit to generate a metric-level output; a fusion operator configured to combine the graph-level output and the metric-level output to produce a joint observation representation; and a policy network configured to process the joint observation 11 representation to generate an action vector corresponding to an optimization for the design of the electrical circuit.

In some cases, the graph processing layer comprises one or more graph convolutional network (GCN) layers configured to propagate information across a topology of the electrical circuit.

In some cases, the feature vectors associated with the nodes of the graph representation further comprise component-type information and physical property information for the plurality of components.

In some cases, the operating point data for a transistor component comprises at least one of a gate-source voltage (vgs), a drain-source voltage (vds), a threshold voltage (vth), or a drain current (id).

In some cases, the artificial intelligence-based system further comprises a projection stage configured to convert the graph-level output into a fixed-dimension vector before the graph-level output is combined by the fusion operator.

In some cases, the artificial intelligence-based system is configured to, after each simulation of the circuit, update the feature vectors with new operating point data obtained by the physics extraction module.

In some cases, the operating point data is normalized based on a data-driven calibration procedure prior to being included in the feature vectors.

In at least another broad aspect, a computer-implemented method is provided for optimizing a design of an electrical circuit, the method comprising: obtaining, via a physics extraction module interacting with a circuit simulator, operating point data for a plurality of components of the electrical circuit, the operating point data representing internal electro-physical quantities of the plurality of components; processing, via a graph processing layer, a graph representation of the electrical circuit to generate a graph-level output, wherein nodes of the graph representation correspond to the plurality of components and are associated with feature vectors comprising the operating point data; processing, via a metric processing network, performance metric data associated with the electrical circuit to generate a metric-level output; combining, via a fusion operator, the graph-level output and the metric-level output to produce a joint observation representation; and processing, via a policy network, the joint observation representation to generate an action vector corresponding to an optimization for the design of the electrical circuit.

In some cases, processing the graph representation is performed by one or more graph convolutional network (GCN) layers that propagate information across a topology of the electrical circuit.

In some cases, the computer-implemented method further comprises updating the feature vectors with new operating point data obtained by the physics extraction module after each simulation of the circuit.

According to some aspects, the present disclosure provides a non-transitory computer-readable medium storing computer-executable instructions. The computer-executable instructions, when executed, configure a processor to perform any of the methods described herein.

### BRIEF DESCRIPTION OF THE DRAWINGS

The drawings included herewith are for illustrating various examples of articles, methods, and systems of the present specification and are not intended to limit the scope of what is taught in any way. In the drawings:

FIG. 1 is a schematic block diagram of a computing system for simulating and automatically modifying electrical circuits using computational loop and an AI model in accordance with at least some embodiments;

FIG. 2 is a block diagram of a computer in accordance with at least some embodiments;

FIG. 3 is a flowchart diagram of an example method of a circuit design process using the computing system, in accordance with at least some embodiments;

FIG. 4 is a schematic block diagram of a computing system for generating a circuit space using a picture of a circuit, in accordance with at least some embodiments;

FIG. 5 is a flowchart diagram of an example method of a computing system controlling access to a circuit space, in accordance with at least some embodiments;

FIG. 6 is a schematic block diagram of a computing system configured to control access to circuit spaces, in accordance with at least some embodiments;

FIG. 7 is a flowchart diagram of an example method of a computing system providing access to a circuit space and facilitating modification of the same, in accordance with at least some embodiments;

FIG. 8 is another schematic block diagram of a computing system configured to control access to circuit spaces, in accordance with at least some embodiments;

FIG. 9 and FIG. 10 are each a flowchart diagram of example methods of a computing system controlling access to a circuit space, in accordance with at least some embodiments;

FIG. 11 is another schematic block diagram of a computing system configured to simulate a circuit and measure performance data, in accordance with at least some embodiments;

FIG. 12 is another schematic block diagram of a computing system configured to simulate a circuit and measure performance data, in accordance with at least some embodiments;

FIG. 13 is another schematic block diagram of a computing system configured to simulate a circuit and automatically modify one or more controllable parameters using an AI agent, in accordance with at least some embodiments;

FIG. 14 is a flowchart diagram for computing a graph of a circuit that is suitable for processing by the AI agent, in accordance with at least some embodiments;

FIG. 15A is a schematic circuit diagram of an example circuit, and FIG. 15B is a schematic diagram of a graph representation of the example circuit, in accordance with at least some embodiments;

FIG. 16 is a schematic block diagram of an actor/critic architecture included in the AI agent, in accordance with at least some embodiments;

FIG. 17 is a graphical representation of a graph convolutional neural network (GCN), in accordance with at least some embodiments;

FIG. 18 is a graph showing example results, in accordance with at least some embodiments;

FIG. 19A is a schematic circuit diagram of an example circuit, FIG. 19B is a schematic diagram of an intermediate graph representation of the example circuit, and

FIG. 19C is a schematic diagram of a finalized graph representation of the example circuit, in accordance with at least some embodiments;

FIG. 20A is a schematic diagram of an actor/critic architecture, and FIG. 20B is a graphical representation of a GCN, in accordance with at least some embodiments;

FIG. 21 is a graph showing example results, in accordance with at least some embodiments;

FIG. 22 is a graphical representation of a GCN, in accordance with at least some embodiments;

FIG. 23 is a graph showing example results, in accordance with at least some embodiments;

FIG. 24 is a graphical representation of a GCN, in accordance with at least some embodiments;

FIG. 25 is a graph showing example results, in accordance with at least some embodiments;

FIG. 26 is a schematic diagram of an actor/critic architecture, in accordance with at least some embodiments;

FIGS. 27 and 28 are graphs showing example results, in accordance with at least some embodiments;

FIG. 29 is a schematic diagram of an actor/critic architecture, in accordance with at least some embodiments;

FIG. 30 is another schematic diagram of the actor/critic architecture shown in FIG. 29, in accordance with at least some embodiments;

FIG. 31 is a graph showing example results, in accordance with at least some embodiments;

FIGS. 32 to 35 are screenshots of example user interfaces for interacting with the computing system, in accordance with at least some embodiments; and

FIG. 36 is a schematic block diagram illustrating an architecture of an artificial intelligence-based system for optimizing a circuit design, in accordance with at least some embodiments.

### DETAILED DESCRIPTION

Existing circuit optimization methods often face limitations in adaptability and scalability. Conventional approaches rely on static optimization algorithms and lack the ability to adapt to diverse circuit configurations and design objectives. In some cases, the systems and processes described herein addresses these challenges by introducing a dynamic reinforcement learning environment generation system, enabling users to leverage a multitude of dynamically generated neural networks for circuit and system optimization.

In some cases, the system includes multiple dynamically generated reinforcement learning based computing environments. In some cases, the system generates reinforcement learning computing environments for deep neural network training. These environments capture design parameters and variables, measurements, optimization requirements and integrate with simulation and emulation tools. In some cases, these dynamically generated environments address specific optimization challenges, offering users a wide range of options to optimize their circuits effectively.

In some cases, the system includes multiple dynamically generated neural networks. In some cases, the system provides users with access to a diverse set of dynamically generated neural networks. In some cases, these neural networks are tailored to address specific optimization challenges, offering users a wide range of options to optimize their circuits effectively.

In some cases, the system includes a user-driven agent selection user interface. Users have the autonomy to select and customize reinforcement learning agents based on their unique requirements and preferences. With the flexibility to choose from multiple network configurations, users can tailor optimization strategies to meet specific design objectives.

In some cases, the system includes reinforcement learning modules. In some cases, the system seamlessly integrates reinforcement learning computations into circuit simulations, enabling continuous learning and adaptation. Through iterative optimization cycles, the system learns from user feedback and refines its optimization algorithms to achieve improved results over time.

In some cases, the system provides scalability and adaptive optimization. The dynamic nature of the system allows for scalable and adaptive optimization solutions. In some cases, whether optimizing individual components or entire circuit systems, the system provides optimization capabilities for circuits of varying complexity.

In some cases, the system provides enhanced circuit performance. including improved power efficiency, signal integrity, and reliability. By leveraging dynamically generated neural networks, the system improves circuits to meet performance requirements.

In some cases, the system provides flexibility and customization. The system provides a user interface that facilitates selection and customization of neural networks, which can be used to tailor optimization computations to suit specific design objectives, constraints, and preferences.

In some cases, the system streamlines the circuit design process and reduce development costs by automating and accelerating the circuit optimization process. In some cases, this reduces time and resources for generating prototypes.

In some cases, the system facilitates continuous improvement through iterative optimization cycles and reinforcement learning. As data accounts interact with the system and provide feedback, the optimization algorithms evolve, leading to ongoing performance enhancement and innovation.

In some cases, the system and processes described herein are applicable to the semiconductor industry, enabling semiconductor companies to improve chip designs for performance and efficiency.

In some cases, the system and processes described herein are applicable to industrial electronics manufacturers to improve the performance and reliability of electronic devices and systems, industrial machines and plants, and robotics.

In some cases, the system and processes described herein are applicable to consumer electronics manufacturers to improve the performance and reliability of electronic devices.

In some cases, the system and processes described herein are applicable to researchers in circuit and system optimization and machine learning.

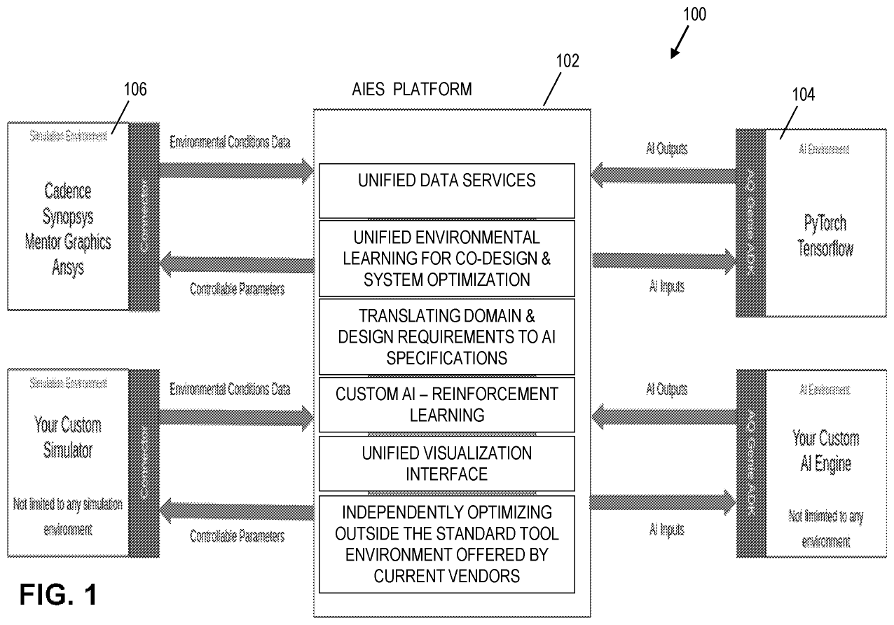

Turning to FIG. 1, an example system 100 is shown that uses artificial intelligence (AI) modules for designing and simulating electrical circuits. The system 100 includes an AI electrical simulation (AIES) platform 102, which is a computing system configured to run neural network models that simulate circuits. Semiconductor designs and spaces (e.g., both herein called circuit spaces) are allocated, offered by circuit designers or owners of such spaces for access (e.g., in some cases via licensing) for short durations. This is called micro licensing and is generally done through an auction-based approach.

In some cases, circuit spaces are designed by the system using AI algorithms and reinforcement learning.

In some cases, AI models are used to generate circuit spaces and associated circuit space circuits.

In some cases, generated circuit spaces circuits, data, and semiconductor designs are sent back to the circuit designer for the circuit designer to start setting a base price for provision to potential buyers.

In some cases, captured circuit space circuits and related data, semiconductor designs circuits, product semiconductor designs data from different locations are sent to centralized platform for aggregation. Aggregation is done with viewing tagging and timestamps of the semiconductor designs data.

In some cases, generated circuit spaces circuits and associated data (including compliance) and product semiconductor designs data, associated with the circuit spaces and otherwise from different locations, are sent to respective manufacturers, producers and designers

In some cases, the AIES platform 102 facilitates access by product manufacturers, producers, and designers to view and bid for circuit spaces offered by the individual circuit designers.

In some cases, circuit space data captured by the circuit designers and circuit designs stored in the AIES platform are transmitted to the manufacturers, designers or circuits producers for compliance checks at predetermined frequency, or according to a predetermined schedule.

In some cases, baseline circuit space data purchases and payments, other data of interest related to circuit space and product compliance in the circuit space from the entities are captured by the AIES platform 102.

Continuing with FIG. 1, in some cases, the AIES platform generates AI inputs, which are sent to an AI computing environment 104, that includes parameters for a circuit, or includes a circuit design, or both. In some cases, the AI computing environment 104 executes a neural network model to generate AI outputs. In some cases, the AI outputs include parameters for a circuit, or includes a circuit design, or both.

The AIES platform 102 uses the AI outputs to modify an existing circuit design, or to generate a new circuit design. The modified circuit design or the new circuit design, and its controllable parameters, are sent to a simulation environment 106, which simulates the modified circuit design or the new circuit design. The simulated data is returned, from the simulation environment 106, to the AIES platform for further analysis.

The AIES platform 102 connects to one or more AI computing environments 104 using one or more connectors. The AIES platform 102 connects to one or more simulation environments 106 using one or more connectors.

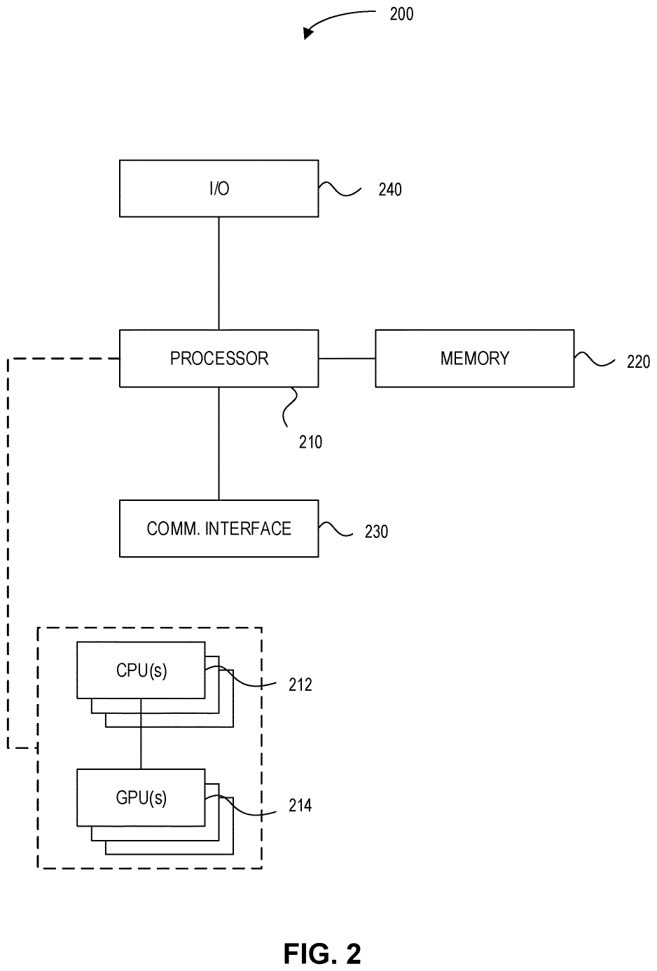

Referring now to FIG. 2, there is illustrated a simplified block diagram of a computer 200 in accordance with at least some embodiments. The computer 200 is also herein interchangeably called a computing system. Computer 200 is an example implementation of a computer such as AIES platform 102, a user device, an AI computing environment 104, and a simulation environment 106. Computer 200 has at least one processor 210 operatively coupled to at least one memory 220, at least one communications interface (also herein called a network interface), and at least one input/output device 240.

The at least one memory 220 includes a volatile memory that stores instructions executed or executable by processor 210, and input and output data used or generated during execution of the instructions. Memory 220 may also include non-volatile memory used to store input and/or output data—e.g., within a database—along with program code containing executable instructions.

Processor 210 may transmit or receive data via communications interface 230, and may also transmit or receive data via any additional input/output device 240 as appropriate.

In some cases, the processor 210 includes a system of central processing units (CPUs) 212. In some other cases, the processor includes a system of one or more CPUs and one or more Graphical Processing Units (GPUs) 214 that are coupled together. For example, an AI model executes neural network computations on CPU and GPU hardware, such as the system of CPUs 212 and GPUs 214.

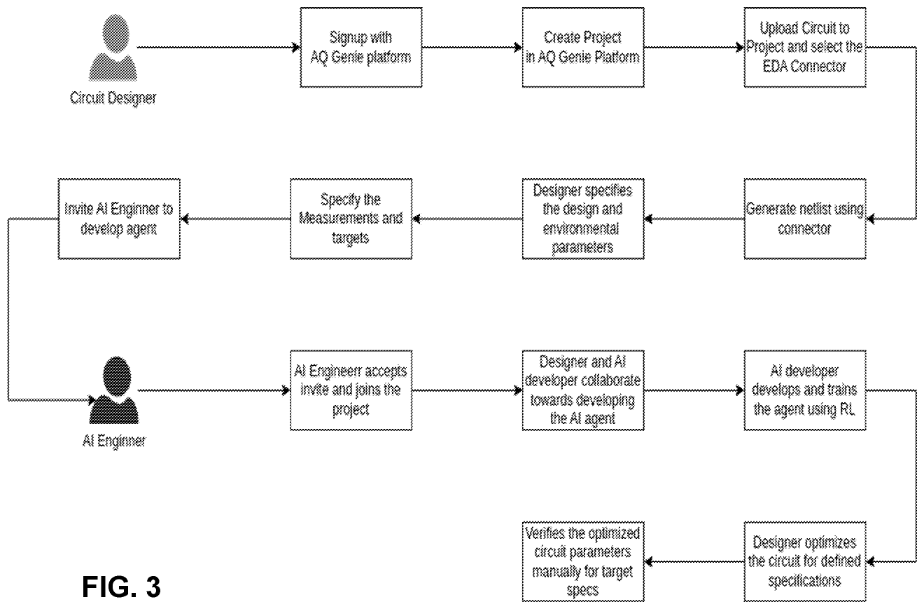

Referring to FIG. 3, a flowchart shows a process for using the AIES platform, which is also considered a centralized cognitive computing platform, and a database of circuits and semiconductor articles. In some cases, the circuits designs (e.g., data files representing circuits) are inputted into the AIES platform via a web browser interface that connects to the AIES platform.

In some cases, the AIES platform generates a circuit space through artificial intelligence and mathematical modeling techniques.

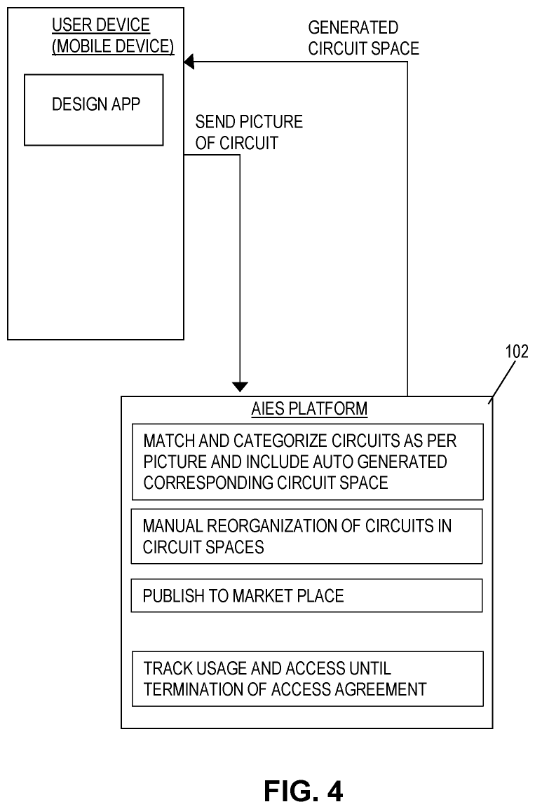

In some cases, the AIES platform provides a user interface for a data account (e.g., operable by a person who is a circuit designer) to add or discard circuit spaces in the captured environment, to change the circuit space categorization [A/B/C] or the space that is being offered (see FIG. 4).

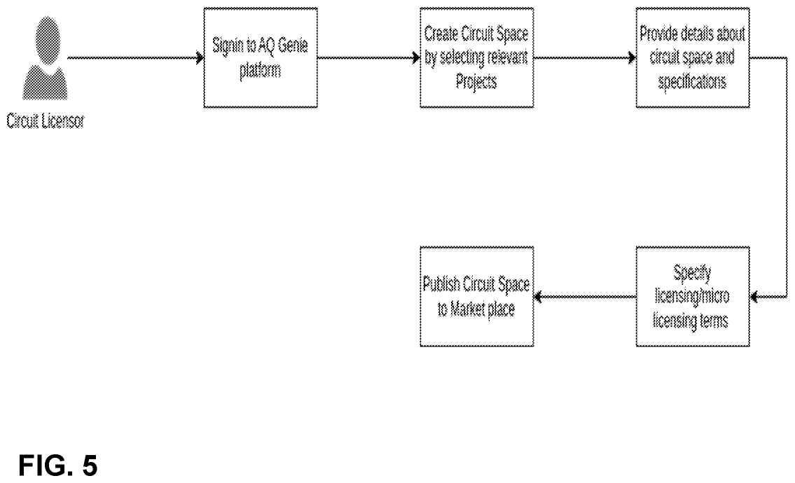

Referring to FIG. 4 and FIG. 5, in some cases, the system captures circuit spaces using a smart phone application, and controls access to the circuit spaces using the smart phone application.

After a picture is captured using the smartphone and sent onto the AIES platform, an AI engine in the AIES platform automatically chooses the circuit spaces present in the circuits and categorizes the same.

The created circuit spaces are transmitted to the user device in real time (or near real time) for them to accept, manually add or discard circuit spaces in the captured semiconductor designs.

In some cases, a user interface of the AIES platform facilitates a user to change the circuit space categorization [A/B/C]. In some cases, the user interface can also be used to adjust a value exchange for the created circuit space. In some case, the user interface provides controls to adjust and set the duration of access to a given circuit space.

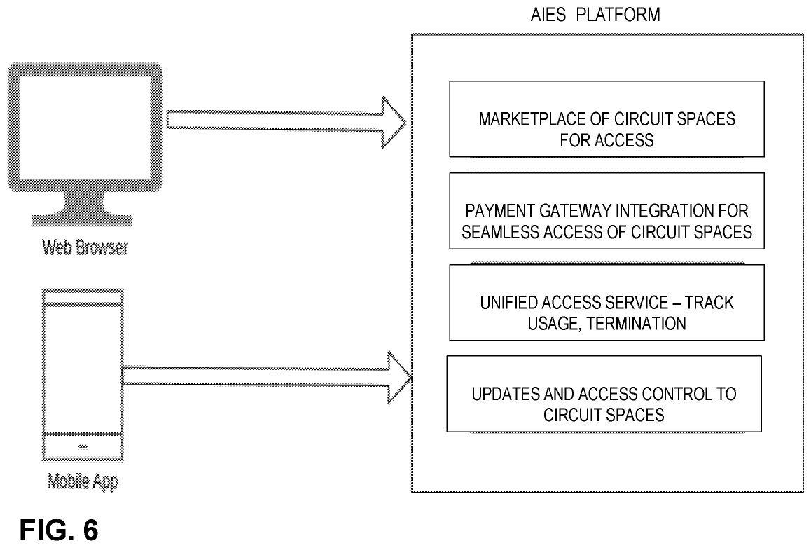

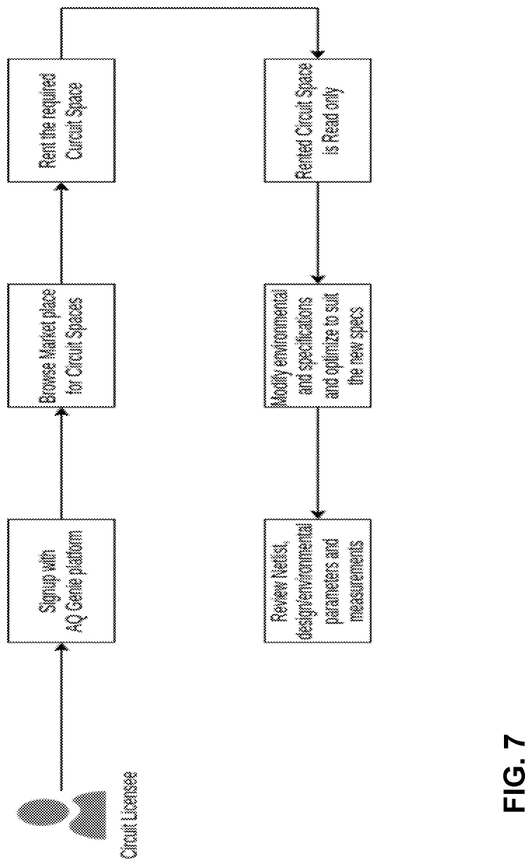

Referring to FIG. 6 and FIG. 7, in some cases, the AIES platform 102 is used to capture circuits of semiconductor designs or circuit spaces (or both) using a smart phone application, or a web browser, and to provide a marketplace for others to access the semiconductor designs or circuit spaces, or both. In some cases, the AIES platform provides a user interface for data accounts to monitor and control the retrieval of the circuits associated or owned by a given data account. In some cases, the circuits retrieved by others (e.g., a consuming data account) are viewed, tagged, time stamped and sent to a cloud computing system for processing and product creation.

In some cases, the AIES platform aggregates the semiconductor designs data, and associated circuits data from multiple outlets for further product availability analytics.

In some cases, the AIES platform includes a graphical user interface that automatically displays the circuit spaces available, licensed and sold using color codes on a viewing-map. The corresponding circuits and categories of the listed circuit spaces are also displayed.

In some cases, data accounts (e.g., associated with entities, circuit developers, and buyers) can click on the viewing map to initiate access to selected circuit spaces, from amongst the displayed circuit spaces. In some cases, the process of initiating access includes defining terms of access (e.g., time period of use, value exchange, etc.). In some cases, the GUI includes controls for a data account to terminate access to a circuit space. In some cases, the AIES platform provides circuits of the circuit spaces that have been made accessible. In some cases, the AIES platform generates compliance reports that indicate whether a given circuit is present in the circuit spaces that have been made accessible to other data accounts.

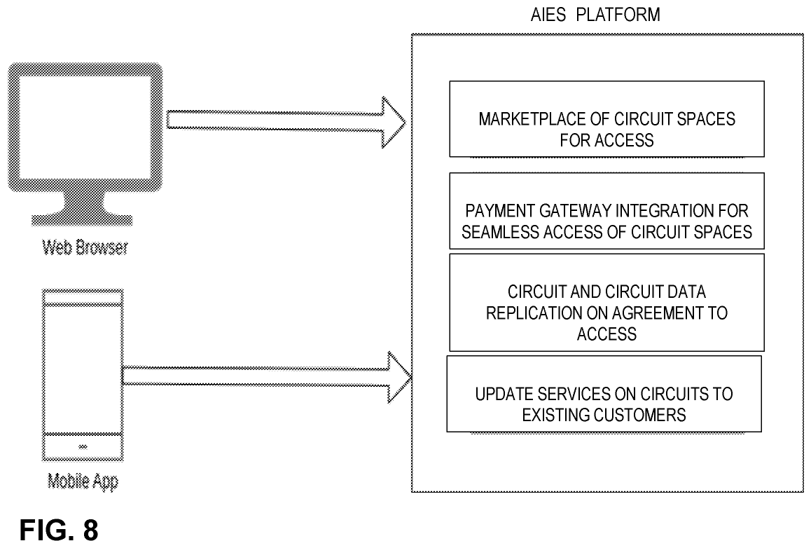

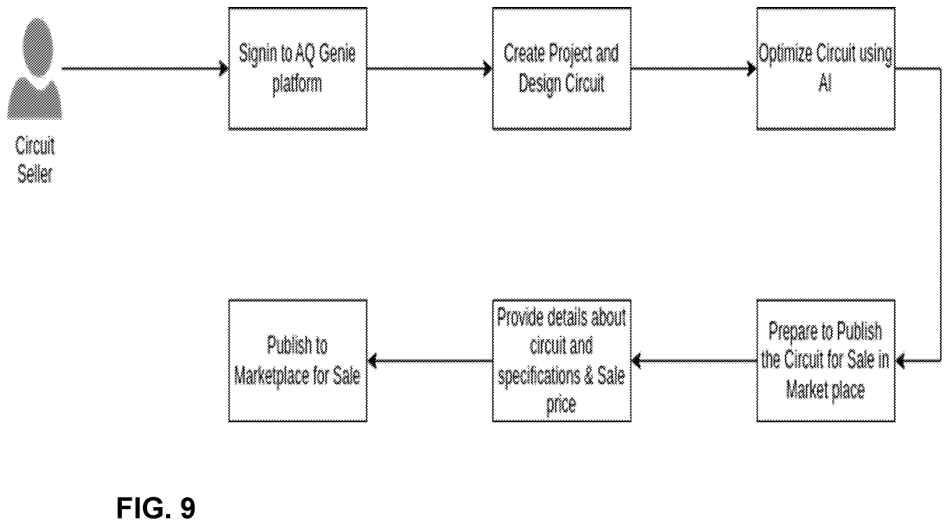

Referring to FIG. 8 and FIG. 9, an AIES platform is provided for circuit designers to capture and sell circuits of semiconductor designs and spaces using a smart phone application. In some cases, all circuits taken by the circuit designers are viewed, tagged, time stamped and sent to the AIES platform for processing and product creation. In some cases, the AIES platform aggregates the semiconductor designs data and associated circuits data from multiple outlets for further product availability analytics.

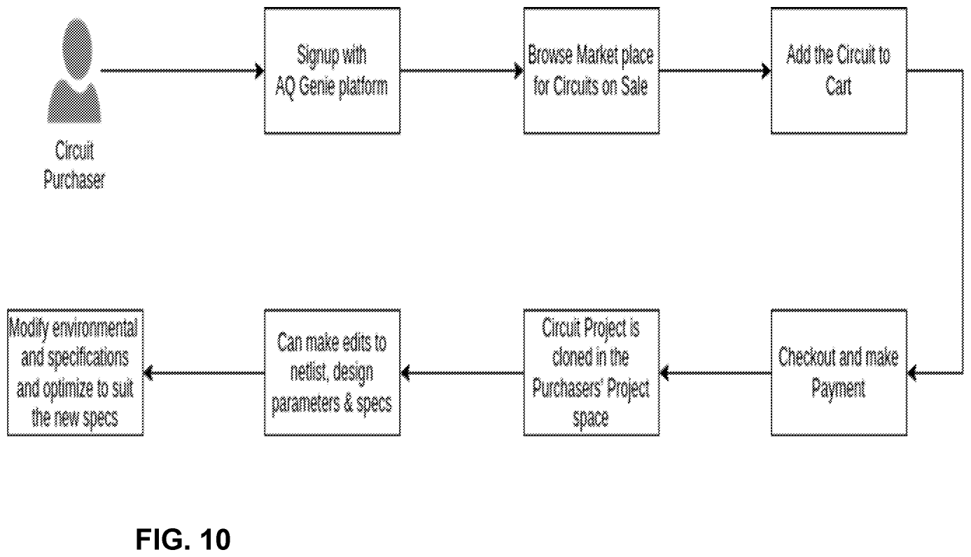

Referring to FIG. 8 and FIG. 10, an AIES platform is provided to receive circuits of the circuit spaces that carry their circuits. The AIES platform includes a GUI that displays which data accounts (e.g., that have been provided access to circuits owned by an owning data account) are currently carrying and utilizing the circuits of the owning data account. In some cases, the AIES platform generates compliance reports that indicate whether the circuits (owned by the owning data account) are present in the spaces according to device fab requirements are reported.

Referring to FIG. 8, FIG. 9 and FIG. 10, an AIES platform is provided to create digital twins of their physical circuits. The AIES platform displays the digital twins of the physical circuits to other data accounts via a GUI. The GUI facilitates other data accounts to request access to one or more digital twins of the physical circuits.

In some cases, the AIES platform tracks and stores data about the data accounts that have viewed the circuits in the GUI (e.g., which represent interested user of the circuits). The data accounts that have viewed the circuits are displayed to the owning data account that owns the circuits; in some cases, this is displayable as a viewing map GUI.

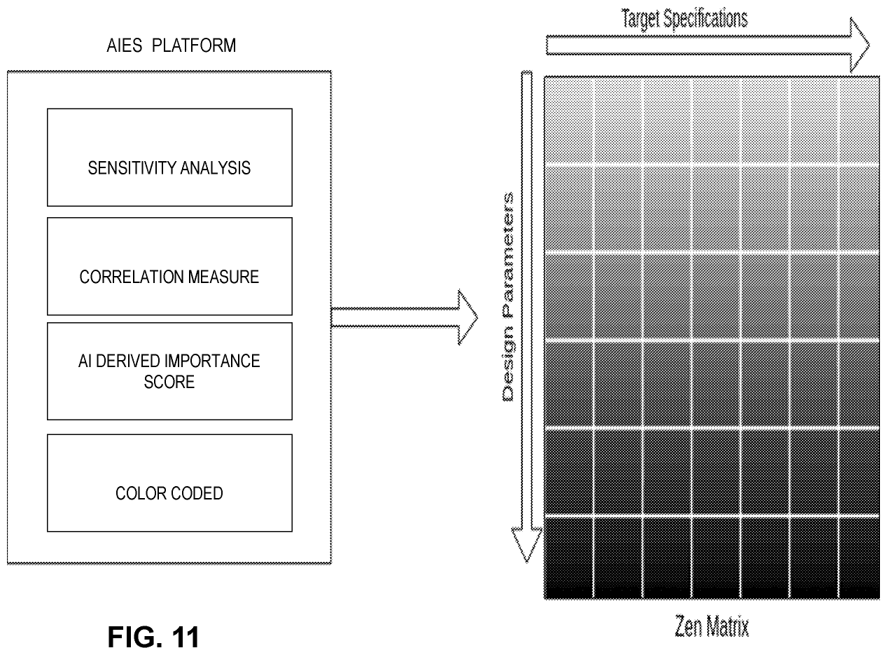

Referring to FIG. 11, an AIES platform is provided to generate and display visualizations of one or more correlations between design parameters in the circuit to the target specifications. In some cases, the AIES platform computes the correlation using sensitivity analysis, correlation measures, and AI derived importance scores. In some cases, the GUI displays the visualization as heat map that is color coded.

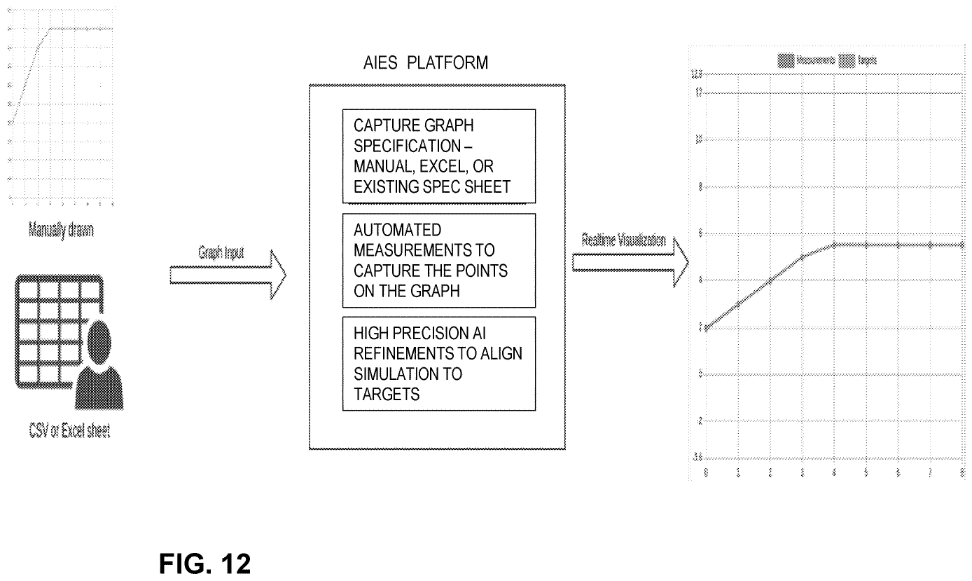

Referring to FIG. 12, an AIES platform is provided to ingest data inputs, via a file or via user input in a GUI, to define graph-based specifications for a circuit design. In some cases, the AIES platform includes a GUI with drawing tools, and a user uses the drawing tools to input graph-based specifications for a circuit design. For example, a drawing tool is manipulated using a pointer (e.g., controllable by a mouse, a touch-screen compatible pen, or a finger) to draw lines defining a graph-based performance that is desirable for a component or a portion of a circuit. In some cases, the AIES platform includes a data interface that ingests Excel or csv data sets, which are then processed by the AIES platform to define graph-based specifications for a circuit design.

In some cases, the AIES platform generates measurement statements dynamically for various input conditions as defined by the graph-based specifications. In some cases, the AIES platform includes one or more AI models that automatically tunes one or more parameters of the circuit design to reach the specified target specifications. For example, multiple iterations of computations are execute by the AIES platform to optimize the parameters to try to reach the target specifications. In some cases, the AIES 8 platform generates a real time (or near real time) visualization of the optimization of the graph specification. In other words, as different iterations of parameters and simulated performances are computed by the AIES platform, these different iterations of parameters and simulated performances are displayed in a graph.

In some cases, an AIES platform and computing process are provided for circuit designers to capture and micro-license circuit spaces using a smart phone application, in a decentralized fashion.

In some cases, an AIES platform and computing process are provided for entities to buy micro-licensed circuit spaces using a web or a smart phone application.

In some cases, an AIES platform and computing process are provided for circuit designers to capture and sell circuits of semiconductor designs and spaces using a smart phone application.

In some cases, an AIES platform and computing process are provided for entities and designers to receive circuits of the circuit spaces that carry their circuits.

In some cases, an AIES platform and computing process are provided for circuit designers to create digital twins of their physical spaces and showcase the same to their customers or the end consumers.

In some cases, an AIES platform and computing process are provided for circuit designers to get insight into the behavior of the circuit using a visualized matrix.

In some cases, an AIES platform and computing process are provided for circuit designers to optimize circuits using graph-based target specifications. This reduces manual effort, with real time visualization providing live feedback and enhanced access for non-experts in semiconductor design.

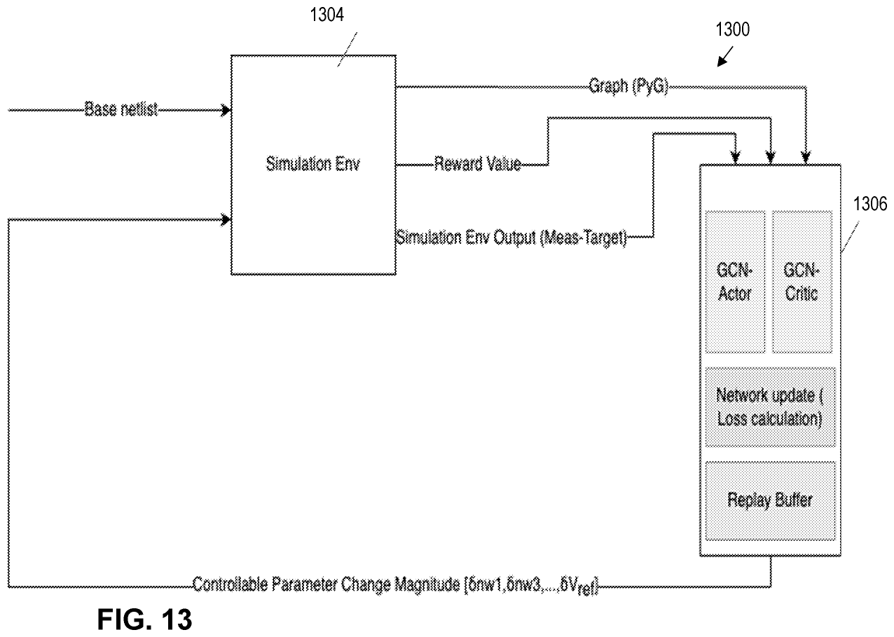

Referring to FIG. 13, a system architecture is shown for a graph convolutional neural network (GCN) with reinforcement learning (RL) system 1300 that is part of the AIES platform 102, or is configured and executed in an AI computing environment 104 connected to the AIES platform 102. The GCN-RL system 1300 can be used with various types of circuits. As an example, a low dropout (LDO) circuit can be optimized using the AIES platform, including the GCN-RL system.

The GCN layer is defined as

$${x}_{υ}^{( ℓ + 1 )} = {w}^{( ℓ + 1 )} {\sum }_{ω ∈ ( υ ) ⋃ \{ υ \}} \frac{1}{{c}_{ω , υ}} \cdot {x}_{ω}^{( ℓ )}$$

where W denotes a trainable weight matrix of shape [num_output_features, num_input_features] and C refers to a fixed normalization coefficient for each edge. In contrast, a single Linear layer is defined as.

$${x}_{υ}^{( ℓ + 1 )} = {W}^{( ℓ + 1 )} {x}_{υ}^{( ℓ )}$$

which does not make use of neighboring node information.

The GCN-RL system 1300 includes a simulation environment module 1304 and a GCN-RL agent 1306 that communicate with each other. The GCN-RL agent 1306, is also herein referred to as an AI agent.

The following operations are executed in the Simulation Environment module 1304:
1. Initialize the base netlist.
2. Initialize the base graph
   a. Convert Circuit to Networkx graph instance and save node_to_param mapping. This mapping captures all nodes with controllable parameters in a dictionary. For instance the controllable parameter of node 10 is nw1.
   b. Convert NetworkX object to the PyG data object. The obtained graph represents nodes and their connection in this step. This step Initialize the base graph structure and nodes features updated in later steps
   c. This link provides detailed information about the PyG data object.
3. Use Actions, to update netlist and graph structure. The action settings have been used so far are:
   a. Magnitude of change (used in V1)
   b. Controllable parameter value (used in V2, V3, and V4)
4. There are two types of nodes in the graph structure. Active nodes represent components with controllable parameters while Fix nodes show components with fixed parameter values. The feature vector of each component type is constructed as follows
   a. Mosfet transistors: [type, w, l, m], where type could be nmos or pmos, encoded using one-hot encoding. If w, l, or m are controllable parameters, they are updated in this step. Otherwise, they remain fixed throughout training.
   b. Voltage source: [type, V, 0, 0], where type is DC and encoded by one-hot encoding. Zero padding is done to keep a consistent feature size for all components.
5. Run NgSpice simulation using the updated netlist
6. The output of the Simulation Env block is the updated graph and simulation results.

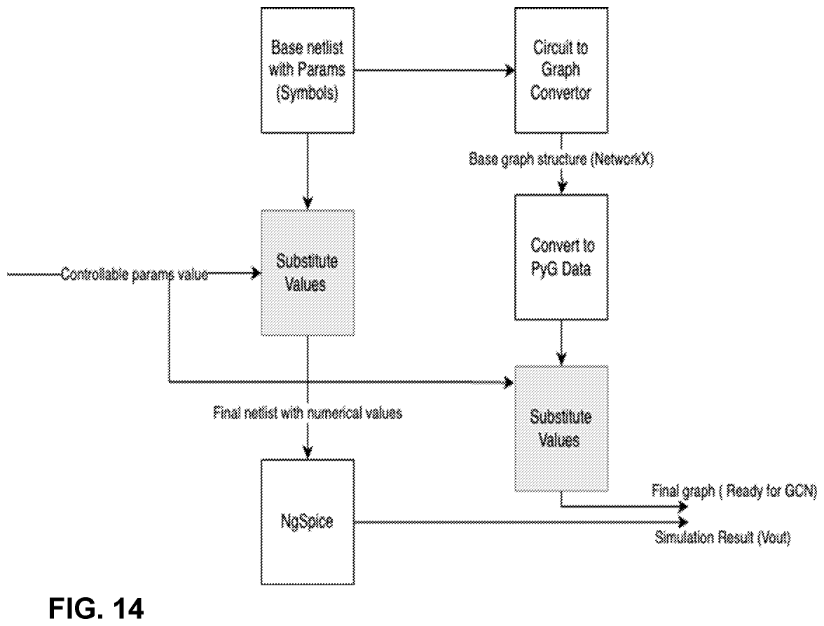

These operations are also shown in FIG. 14.

In some cases, a procedure is executed to convert a circuit into a NetworkX graph object. It should be noted that these operations are designed based on the provided LDO circuit and mainly used to illustrate the operations of the GCN-RL system 1300. It will be appreciated that further operations, in addition or in alternative, are taken to adopt this approach to other types of circuits while adhering to the principles described herein. Below are executable operations to convert a circuit into a NetworkX graph object:
a. Remove any lines beginning with either a “*” or a “.”. These lines contain comments or control instructions and should not be included.
b. Each line follows the following pattern
   i. Id+nets+type+feature
      m0+Ido_bypass Ido_bypass_dis vss vss+nmos+w=1e-6 1=1e-6
   c. Multiple instances of the same component might exist, and all are saved.
   d. A dictionary of components is created based on this pattern. This dictionary includes the following keys for each component: {id, base_id, instance, nets, type, features}. Here's an example:
      m2: {‘id’: ‘m2’, ‘base_id’: ‘m2’, ‘instance’: 1, ‘nets’: [‘vss’, ‘b2’, ‘vss’, ‘vss’], ‘type’: ‘nmos’, ‘features’: {‘w’: 5e-07, ‘l’: 2e-06}}
   e. Nodes contain information of each component. The next step is to identify the edges that connect these nodes.
   f. Identify all component IDs connected to each net name.
   g. Connect components that share the same net by adding an edge between them. Here is the code output:
      m0↔m20, connected via nets: [‘Ido_bypass’, ‘vss’, ‘vss’, ‘vss’, ‘vss’]

In some cases, the GNC-RL agent 1306 is configured to execute a soft actor-critic (SAC) algorithm. The SAC algorithm is an off-policy actor-critic deep RL algorithm based on the maximum entropy reinforcement learning framework. In this framework, the actor aims to maximize expected reward while also maximizing entropy; for example, to succeed at the task while acting as randomly as possible. In some cases, the GNC-RL agent 1306 learns the topology of a circuit to make the training process more efficient.

### Circuit-to-Graph Mechanism—Embodiment 1

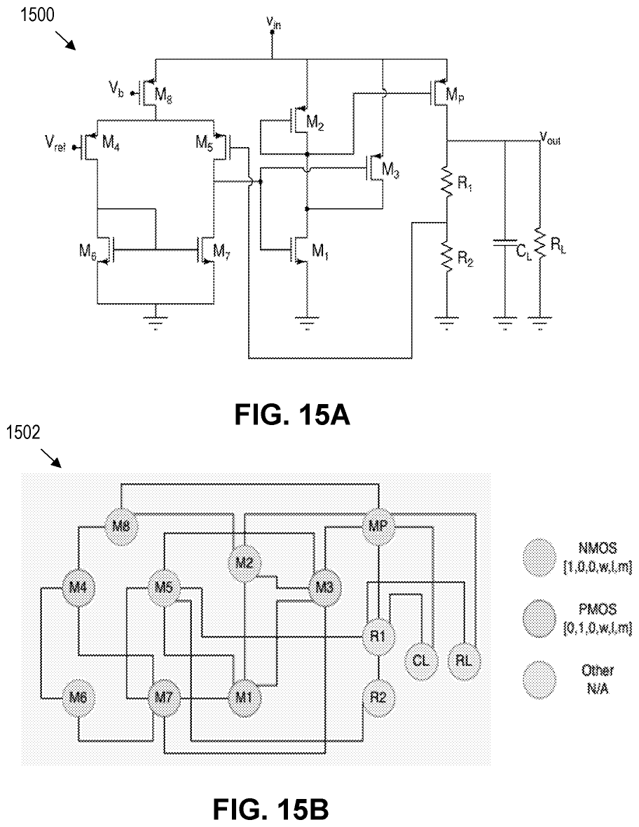

In some cases, the GNC-RL agent uses a circuit-to-graph mechanism, which include all components (except Voltage source) as nodes. FIG. 15A shows the circuit 1500 and FIG. 15B shows the corresponding graph representation 1502 of the circuit 1500.

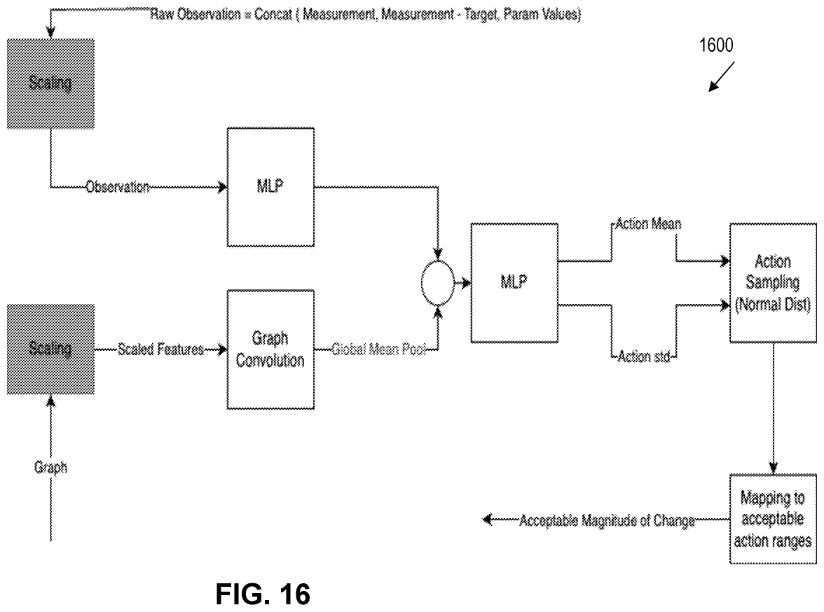

Referring to FIG. 16, and in connection with FIGS. 15A and 15B, in some cases, an actor/critic architecture 1600 is included for the GCN-RL agent 1306. It includes a Multilayer Perceptron (MLP) head for processing observation information and a Graph Convolution head for graphs. The output of these heads are concatenated and are passed through another set of MLP layers to generate action or estimate the state-action value. A MLP head is a Multilayer Perceptron block used as the final output layer of a model, such as in a Vision Transformer (ViT) or similar architecture, to perform task-specific processing like classification.

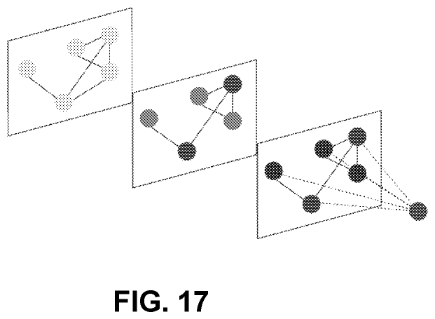

In some cases, the graphical representation for GCN and Global Mean Pool is shown in FIG. 17. In particular, the first MLP structure includes: [Batch_size, #features]→[B_size, 64]→[B_size, 32].
1 The GCN Structure includes: [Batch_size, #nodes #features per node]→[B_size, #nodes, #16]→[B_size, #nodes, #16]→global mean pool (average feature “n” among all nodes)→[B_size, 16]
The MLP output ([B_size, 32]) and GCN output ([B_size, 16]) are concatenated and passed to another MLP.

This generates an Action, which is or includes a magnitude of change in each parameter.

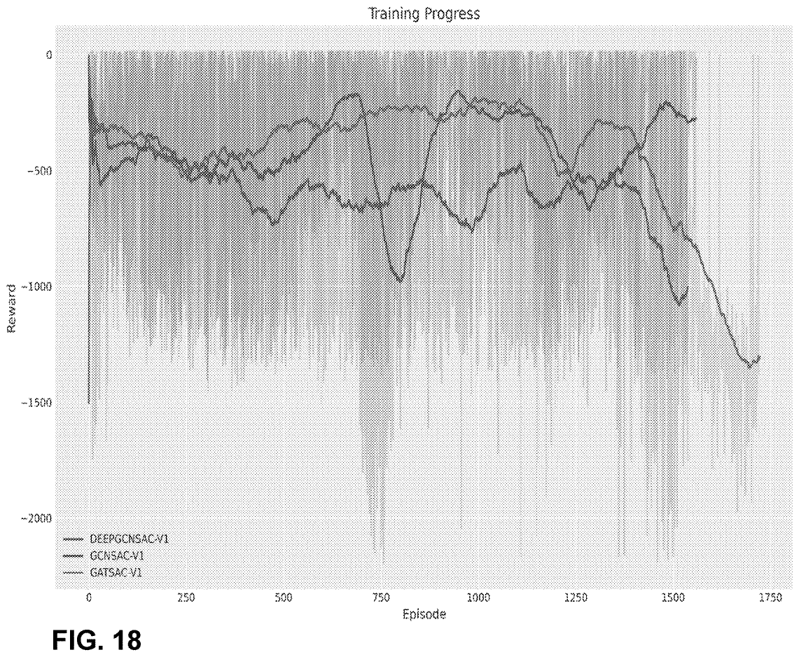

An example of results is shown in FIG. 18. As can be seen, the cumulative reward is not improving and the GCN-RL agent is not able to reach a stable policy. The following versions are focused to solve the instability and random policy issues.

### Circuit-to-Graph Mechanism—Embodiment 2

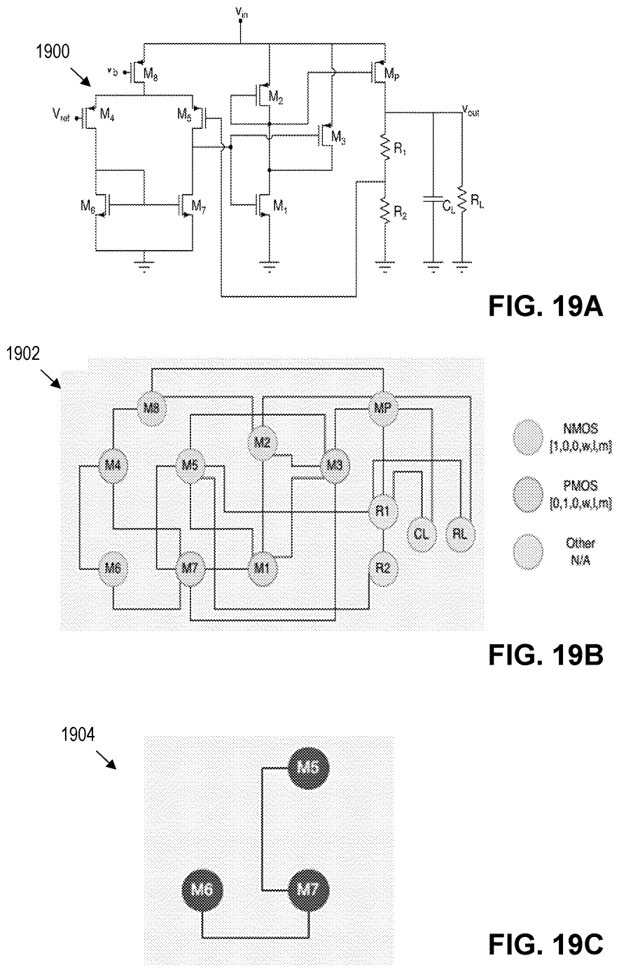

In another embodiment or version of a circuit-to-graph mechanism, the GCN-RL agent only includes active nodes (e.g., nodes with controllable parameters) and saves the mapping of nodes to controllable parameters. Voltage sources are not considered as a node in this version. In the provided example M5, M6, M7, and Vref have controllable parameters. The controllable parameters of these components are nw1,nw1, pw1, and vref respectively. If the node index for M5, M6, and M7 are 1,2,3, then the mapping dictionary for this example would be {1: {nw1}, 2: {nw1}, 3: {pw1}}. Feature list for each transistor: [on-hot encoding of type, w]. It is assumed that the only controllable parameter is W to validate this architecture. Other parameters like length and m are included in the later versions. FIG. 19A shows an example circuit 1900, FIG. 19B shows an example intermediate graph 1902 corresponding to the circuit 1900, and FIG. 19C shows a finalized graph 1904 that has been automatically derived from the intermediate graph 1902 based on identifying the active nodes and their respective connections.

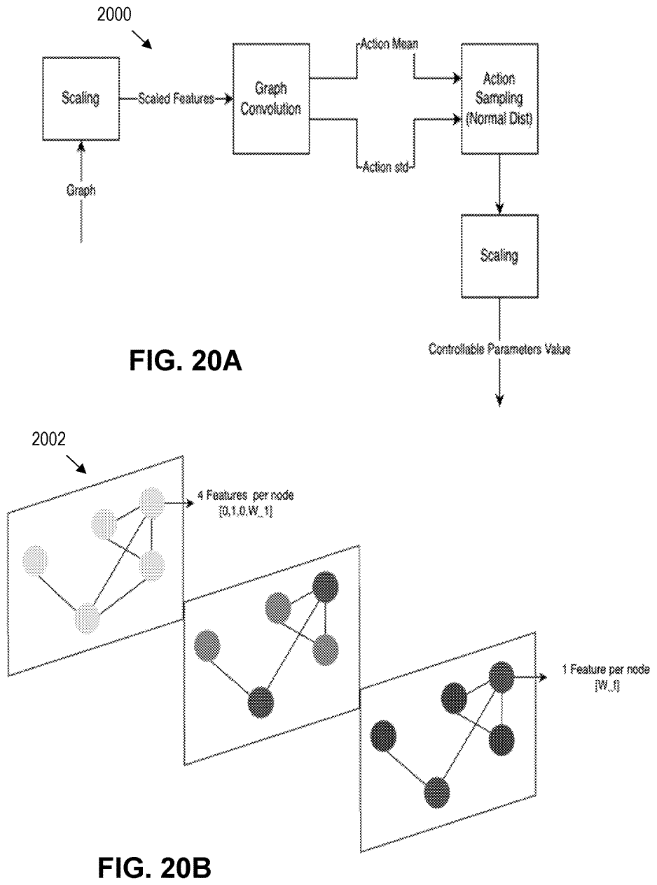

In relation to the embodiment shown in FIGS. 19A, 19B, and 19C, and now referring to FIG. 20A, an actor/critic architecture 2000 is included for the GCN-RL agent 1306. The GCN is used to process the graph and directly output the action. The Action is the controllable parameter value (not the magnitude of change). The graphical representation 2002 for GCN is shown in FIG. 20B. The GCN Structure includes:

[Batch_size, #nodes #features per node]→[B_size, #nodes, 8]→[B_size, #nodes, 1]. The feature vector of each node is used directly to update its corresponding controllable parameter value. If there are multiple nodes representing the same controllable parameter, the final value of this parameter is the average of all values provided by different components.

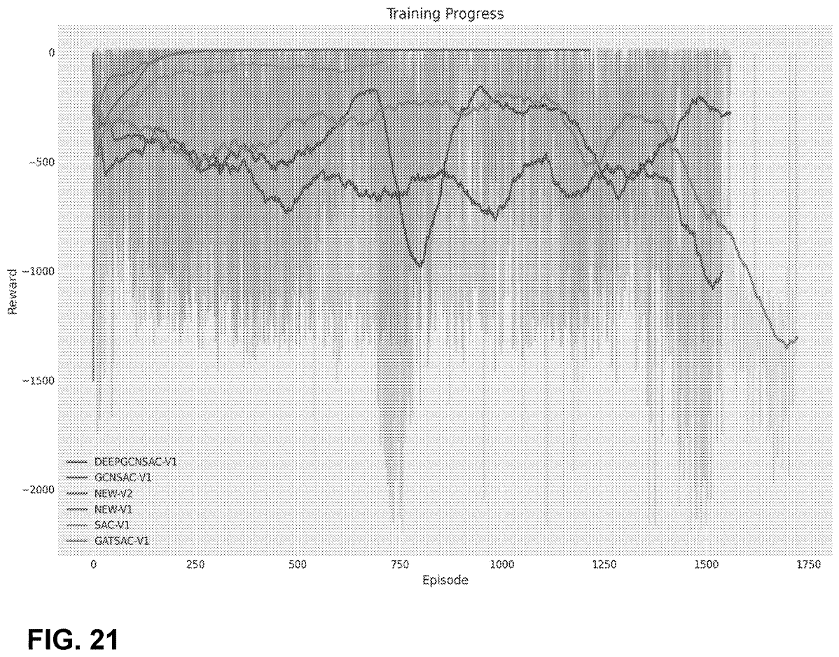

The results are shown in FIG. 21, which show that the reward curve is improving in time and the GCN-RL agent reaches a stable policy. With this embodiment, all information related to the circuit is not being considered by focusing on the components with controllable parameters. In some cases, this is addressed in the embodiments described below.

### Circuit-to-Graph Mechanism—Embodiment 3

In some cases, a third circuit-to-graph mechanism is similar to Embodiment 2. However, in this embodiment, the GCN-RL agent only considers active components and components coming with fixed values. In other words, all components, whether active or fixed, are considered in this version.

In some cases, voltage and load sources are not represented in the graph. The final graph includes transistors, resistors, or capacitors. In some cases, Vref is not considered as a controllable parameter. It is randomly selected within the acceptable range.

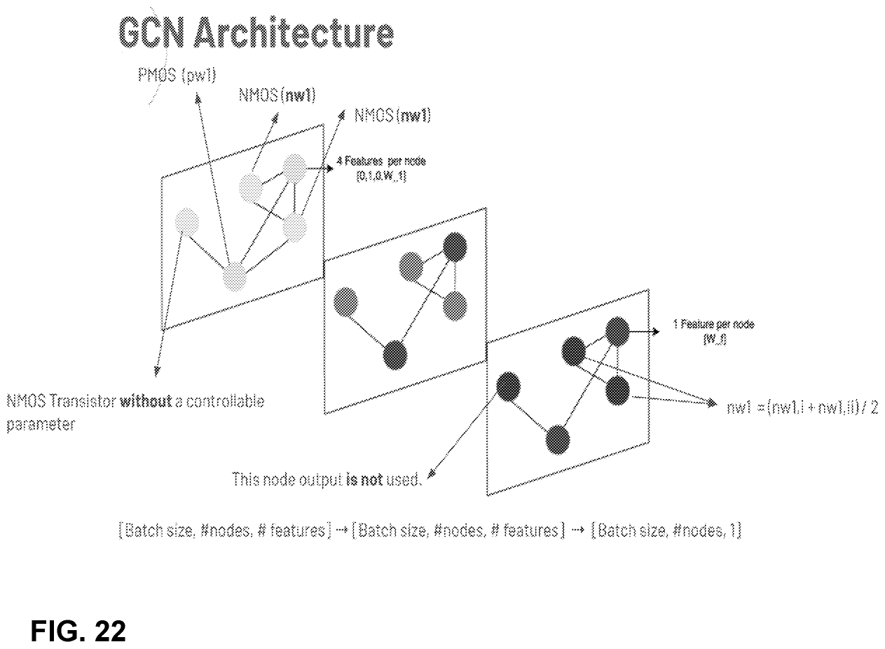

The actor/critic architecture is the same as shown in Embodiment 2. The graphical representation is shown in FIG. 22. The output of each node is used to optimize its corresponding controllable parameter: (a) final value of each controllable parameter is the average of outputs of all nodes representing it; and (b) the output of fixed nodes are disregarded.

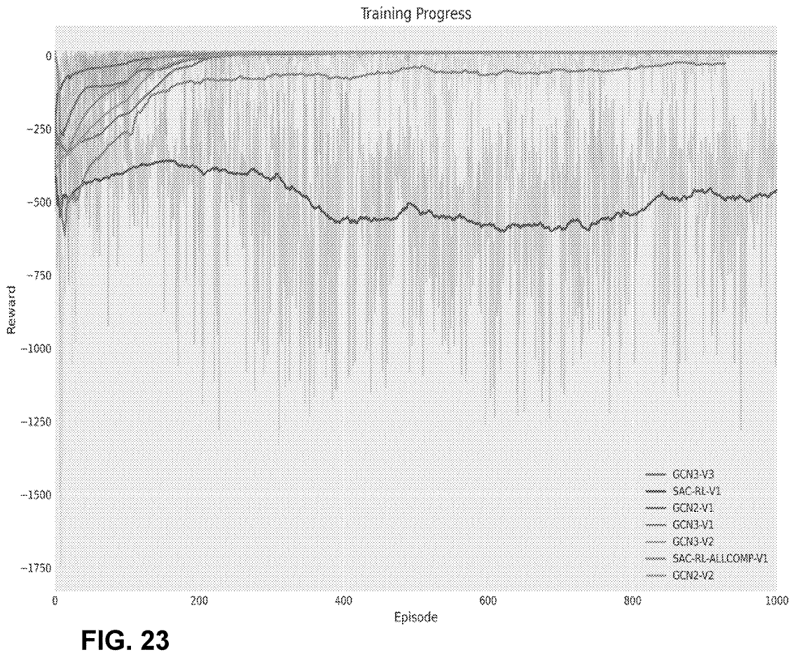

The results are shown in FIG. 23. The GCN-RL agent shows acceptable behavior given the plot. The reward is improving and policy is stable. In some cases, this is due to including all components in the simulation whether they have a controllable parameter or not.

### Circuit-to-Graph Mechanism—Embodiment 4

In some cases, in another embodiment of a circuit-to-graph mechanism, the GCN-RL agent only considers active components and components coming with fixed values, and includes all voltage/load sources as nodes. These voltage/load sources are also herein called virtual nodes. The extended feature list for nodes is provided below:
1 For transistors: [type, w, L, m]; type=[nmos,pmos]
2 For voltage sources: [type, v,0,0]; type=[dc]

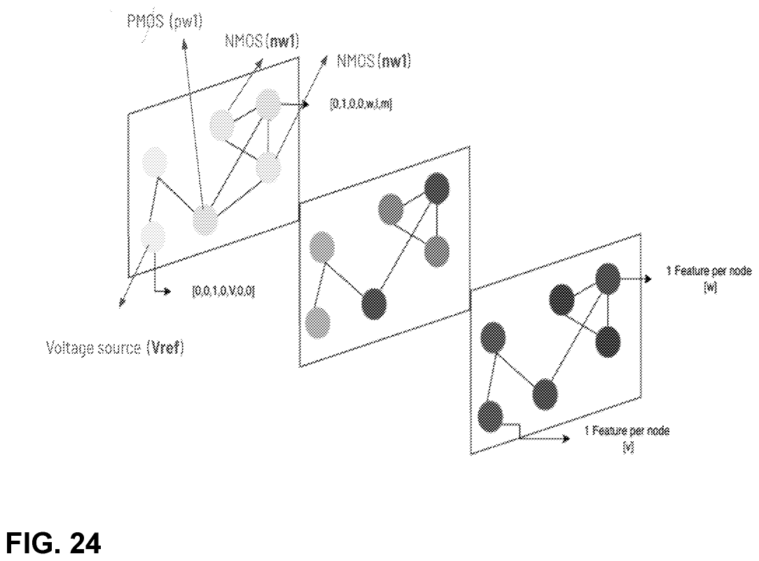

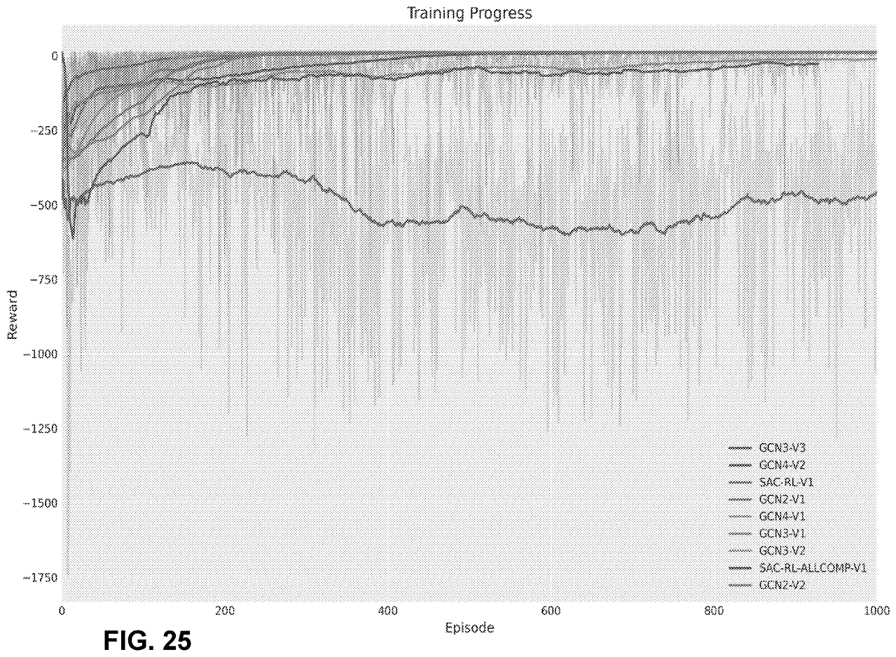

The actor/critic architecture is the same as shown in Embodiment 3. The graphical representation of the Actor part is shown in FIG. 24. The results are shown in FIG. 25. The GCN-RL agent is showing acceptable behavior given the plot (e.g., reward is improving and policy is stable).

In some cases, there are alternative approaches to calculate each controllable parameter value. Currently, in the last layer of the GCN, some nodes produce outputs that are ignored because their values are fixed and do not change during training. In some cases, the GCN directly predicts the values of controllable parameters. In other cases, the GCN is configured to learn the circuit's topology and structural relationships.

### Circuit-to-Graph Mechanism—Embodiment 5

In some cases, in another embodiment of a circuit-to-graph mechanism, the GCN-RL agent only considers active components and components coming with fixed values, and includes all voltage/load sources as nodes (also called virtual nodes). This is the same process in Embodiment 4.

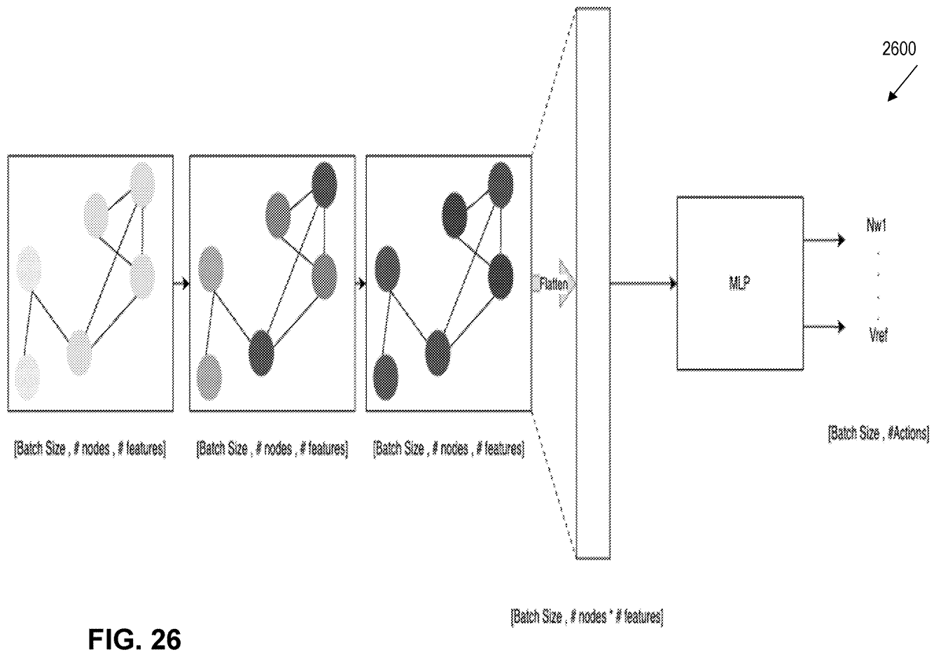

The actor/critic architecture is different in this Embodiment 5. The GCN is used to only to capture circuit topology, and is not used to generate actions. The last GCN layer is flattened and is sent to another MLP for generating final controllable parameters values. The MLP output, after proper scaling, is directly applied to the circuit. Referring to FIG. 26, the graphical representation of the actor/critic architecture 2600 is shown.

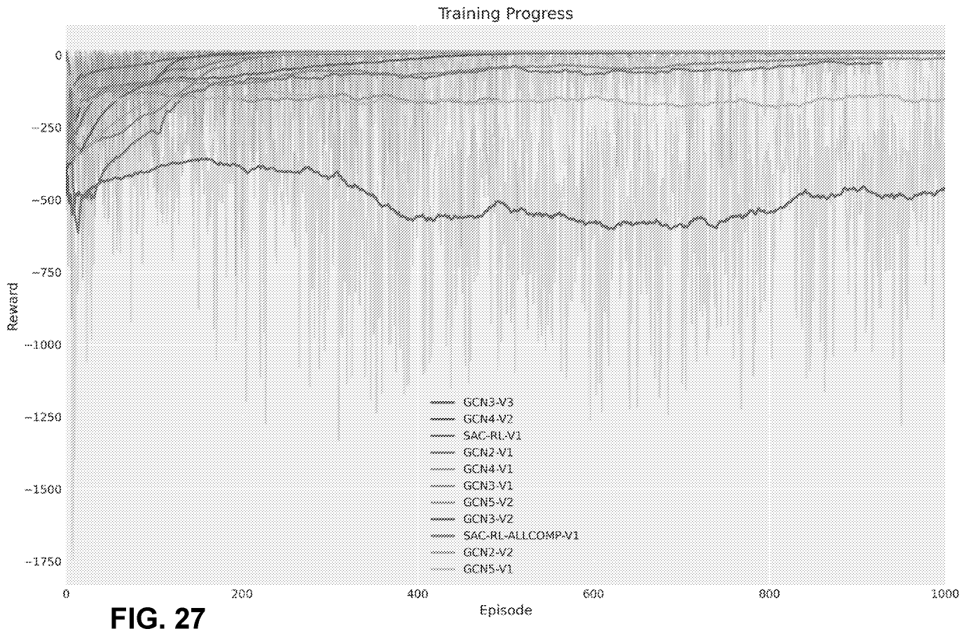

The results of the GCN-RL agent are shown in FIG. 27. In some cases, the GCN-RL agent shows interesting behavior at the beginning of the training but it's not able to recover later and continue learning the proper policy.

### Circuit-to-Graph Mechanism—Embodiment 6

In some cases, in another embodiment of a circuit-to-graph mechanism, the GCN-RL agent only considers active components and components coming with fixed values, and includes all voltage/load sources as nodes (also called virtual nodes). This is the same process in Embodiment 4.

The actor/critic architecture configured in Embodiment 6 is the same as in Embodiment 5. However, the action setting is different. In Embodiment 6, the action setting is the magnitude of change for each controllable parameter. By contrast in Embodiment 5, the action setting is directly optimizing the controllable parameter value.

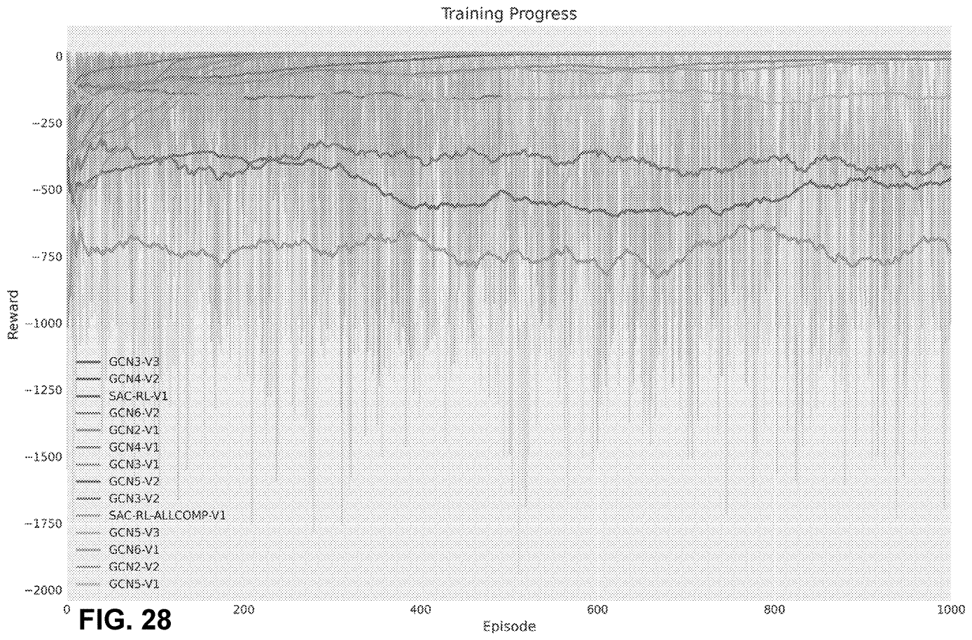

The results are shown in FIG. 28.

### Circuit-to-Graph Mechanism—Embodiment 7

In some cases, in another embodiment of a circuit-to-graph mechanism, the GCN-RL agent only considers active components and components coming with fixed values, and includes all voltage/load sources as nodes (also called virtual nodes). This is the same process in Embodiment 4.

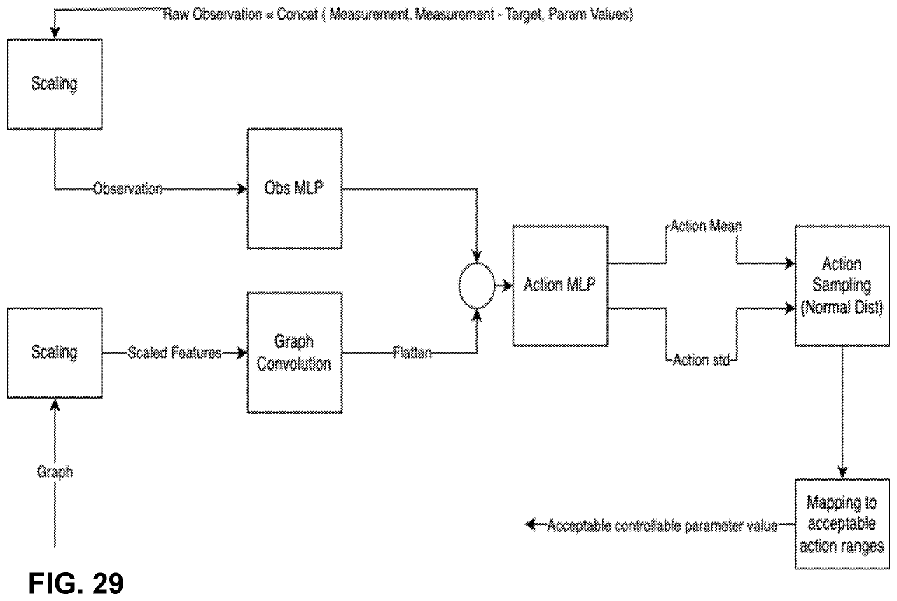

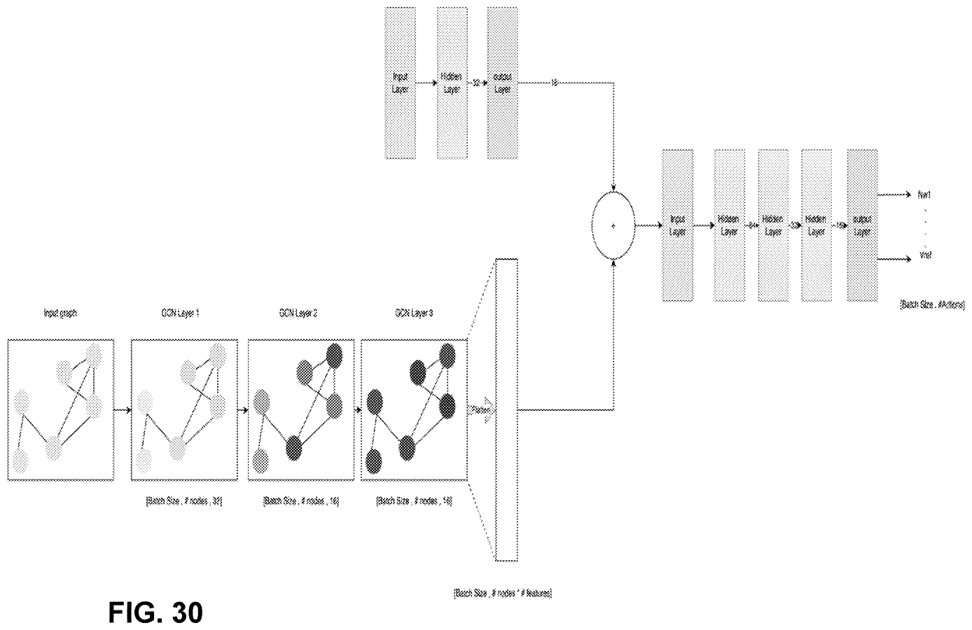

The actor/critic architecture configured in Embodiment 7 is similar to that in Embodiment 5, but also includes an additional MLP head for observation. The actor/critic architecture is shown in FIG. 29. The graphical representation of the layers is shown in FIG. 30. In some cases, there are more MLP layers and more GCN layers. In some cases, a batch normalization module is added after each GCN layer.

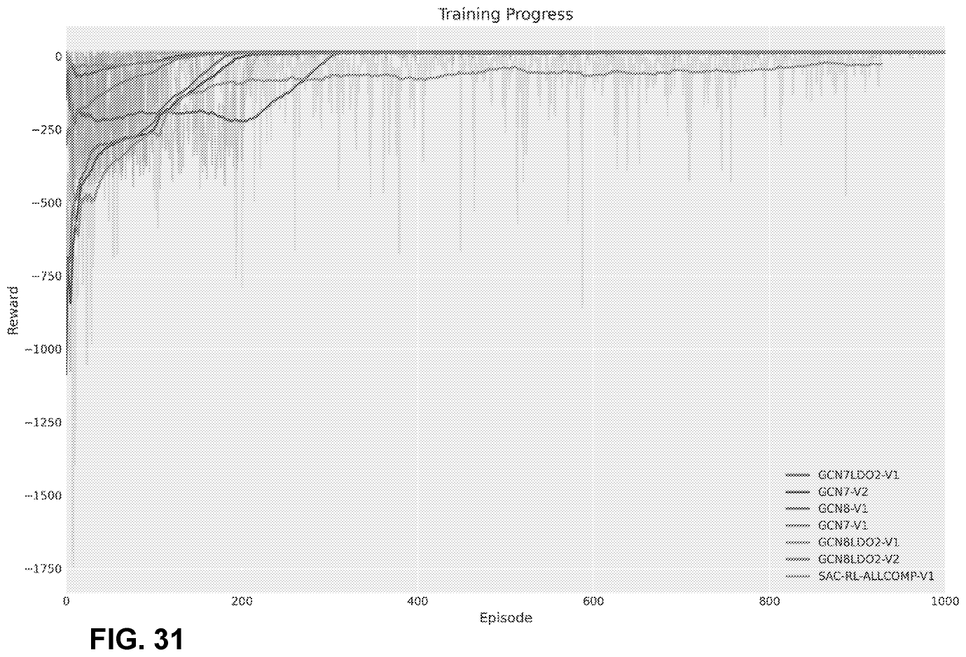

The results of the GCN-RL agent configured according to Embodiment 7 are shown in FIG. 31, which show an improved performance.

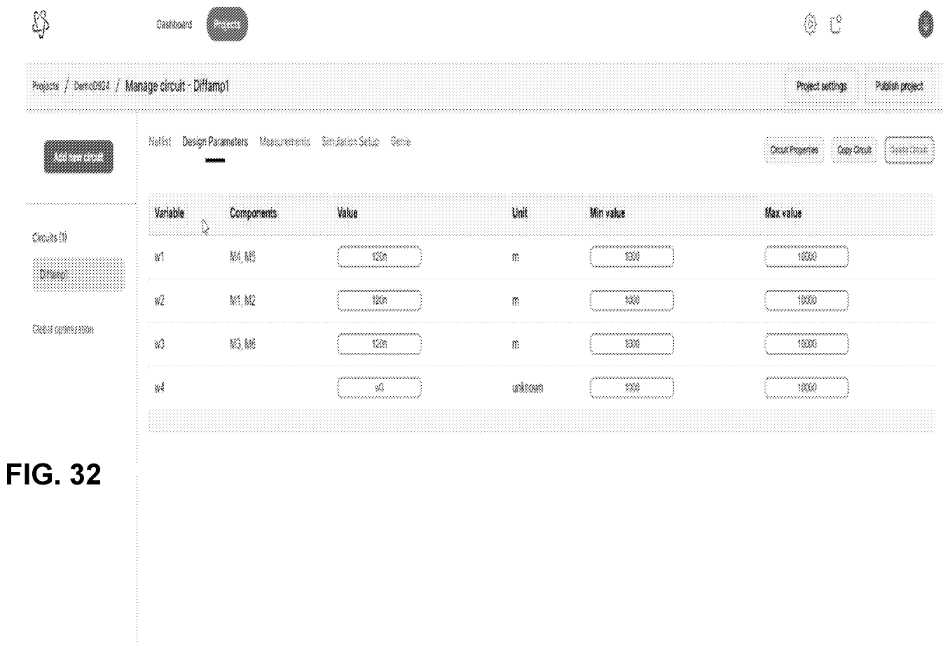

Referring to FIGS. 32, 33, 34, and 35, various embodiments of a user interface of the AIES platform are provided.

FIG. 32 shows a user interface for selecting design parameters for a circuit. The user interface includes controls to change a default value, and set a range of values (MIN and MAX). The AI agent will run the simulation between the range of the values. In some cases, the user selects the range due to design requirements/constraints.

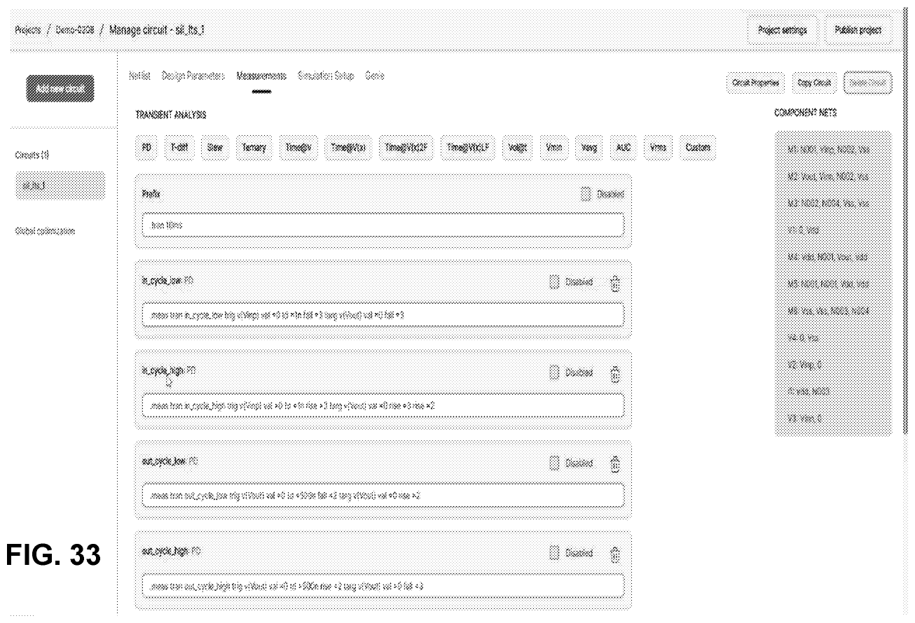

FIG. 33 shows a user interface for defining measurements of the circuit. The user interface includes controls for a user to select measurement to track. In some cases, the computing system automatically selects the measurements to track when executing a simulation of the circuit.

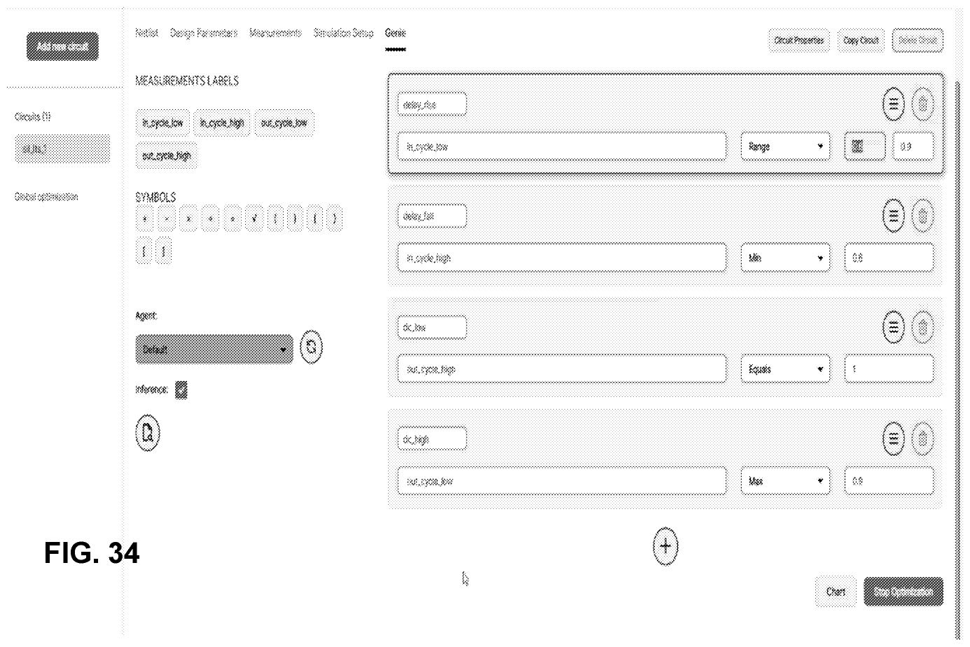

FIG. 34 shows a user interface for adjusting parameters of the AI agent. In some cases, the user interface in FIG. 34 provides controls to select the target specifications. In some cases, a target specification for a parameter is a range of values, or an exact value (e.g., “equals” operator), or a threshold value (e.g., “minimum” operator or “maximum” operator). The AI agent optimizes the circuit to achieve the one or more target specifications.

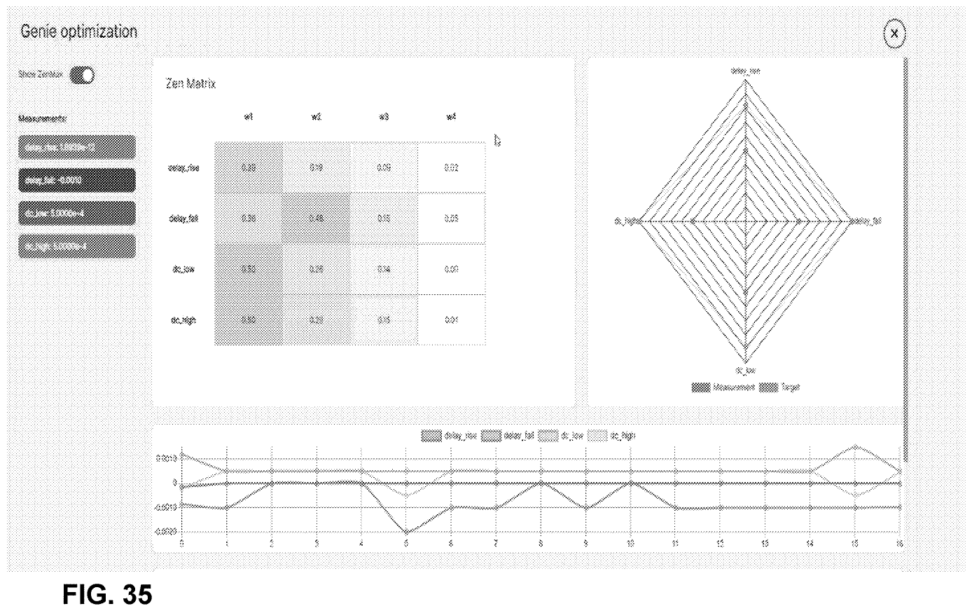

FIG. 35 shows a user interface that displays the iterations of the simulation results of the circuit in real time or near real time. In some cases, if there are different target specifications, the weightings for the target specifications are also shown. In the example shown in FIG. 35, there were 16 iterations of simulating the circuit and user interface shows the simulated measurement results of each iteration as a graph.

In some cases, systems and methods are also provided for optimizing electronic circuit designs using artificial intelligence, such as a physics-informed reinforcement learning agent that leverages internal device-level operating conditions to enable more efficient and effective design optimization. In particular, existing reinforcement learning (RL) approaches to analog circuit sizing treat the environment as a black box. Some existing do not have visibility into the internal physical behavior of the circuit. This abstraction limits the existing system's ability to form meaningful design strategies.

In some cases, an artificial intelligence-based system is configured to obtain and process internal device conditions, such as transistor operating regions. For example, the artificial intelligence-based system is augmented to include an observation space with SPICE operating point (OP) data. After each simulation, the agent receives not only external performance metrics but also the internal electro-AI physical state of each component. These OP quantities are not controllable parameters; they are variables that reflect the self-consistent behavior of the circuit under the current design. By embedding this information as node features in a Graph Neural Network (GNN), the policy shifts from a purely structural representation to a physics-informed one, enabling reasoning over both topology and device-level behavior.

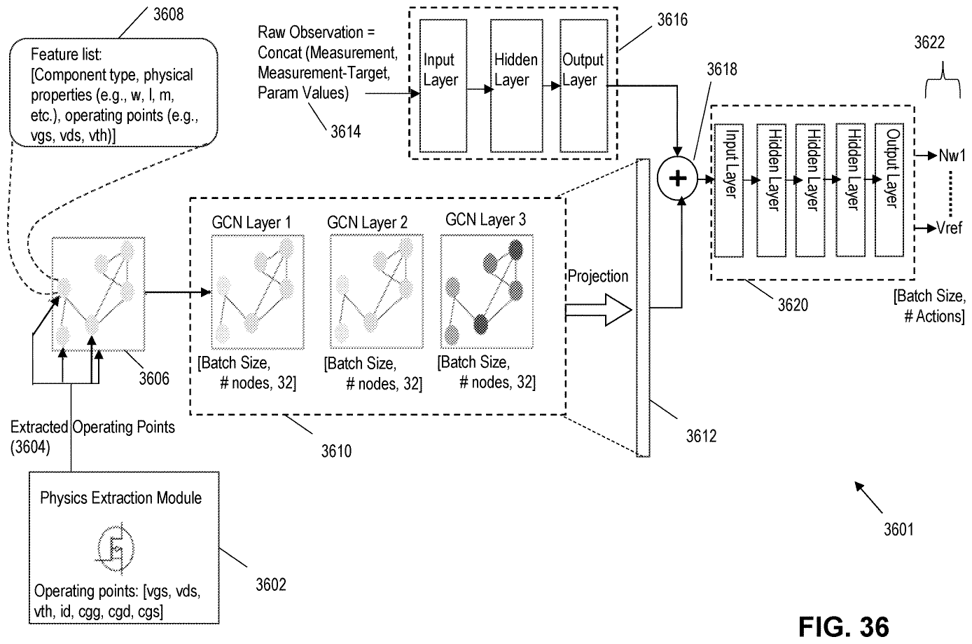

Turning to FIG. 36, a detailed architecture of an artificial intelligence-based system 3601 for optimizing a circuit design is shown. In some cases, the system 3601 is configured to combine simulator-derived physical operating points with circuit topology information and performance measurements to generate design optimization actions.

The system 3601 comprises a physics extraction module 3602. The physics extraction module 3602 is configured to interact with a circuit simulator (not shown) to obtain or extract operating point data 3604 associated with a plurality of components within a circuit. The extracted operating points 3604 represent internal electro-physical quantities produced by the simulation, such as transistor operating conditions, which reflect the self-consistent physical behavior of the circuit under its current design parameters. For example, for a transistor component, the operating point data 3604 may include values for gate-source voltage (vgs), drain-source voltage (vds), threshold voltage (vth), and drain current (id).

In some cases, other operating point data include one or more of, including various combinations, of the following data:

### Geometry/Instance Inputs

l: drawn channel length.
w: drawn channel width.
m: multiplicity, meaning how many identical devices are placed in parallel as one instance.
nf: number of fingers.
sa, sb: layout-dependent distances used for length-of-diffusion/stress effects on the source side and drain side of the gate.
sd: spacing related to the multi-finger layout used in the LOD/stress formulation.
sca, scb, scc: mismatch/statistical well-proximity related instance parameters representing first, second, and third distribution terms for scattered well dopant.
sc: another geometry/layout correction term; in many dumps it is present for compatibility, but its exact use can be simulator/model-version dependent.
min: geometry helper used in BSIM's layout-dependent parasitic calculations, especially when computing effective diffusion area/perimeter/resistance when explicit values are 6 not supplied.

### Source/Drain Geometry

ad: drain diffusion area.
as: source diffusion area.
pd: drain diffusion perimeter.
ps: source diffusion perimeter.
nrd: number of drain diffusion squares, used to compute drain series resistance.
nrs: number of source diffusion squares, used to compute source series resistance.

### Flags/Model Selectors

off: starts the device in the OFF state for operating-point initialization; mainly a convergence aid.
wnflag: simulator-specific width/finger handling flag; in ngspice-related discussions it affects how width and nf are interpreted, so it is not a physical device quantity.
trnqsmod: transient non-quasi-static model selector; 0 means off, 1 means on.
acnqsmod: AC non-quasi-static model selector; 0 means off, 1 means on.
rbodymod: body-resistance network selector.
rgatemod: gate-resistance/intrinsic-input-resistance model selector.
geomod: source/drain connection geometry option for multi-finger layout.
rgeomod: source/drain diffusion resistance geometry option.
   Process-variation/layout-resistance helpers
delvto: instance threshold-voltage shift added to the nominal threshold model; used to represent local variation or mismatch.
mulu0: mobility multiplier; scales carrier mobility for that instance.
xgw: distance from the contact to the gate edge used in gate resistance calculation.
ngcon: number of gate contacts used in the gate resistance model.

### Small-Signal Conductances/DC Operating-Point Quantities

gmbs: body transconductance, ∂D/∂VBS\partial I_D/\partial V_{BS}∂ID/∂VBS.
gm: gate transconductance, ∂ID/∂VGS\partial I_D/\partial V_{GS}∂ID/∂VGS.
gds: output conductance, ∂ID/∂VDS\partial I_D/\partial V_{DS}∂ID/∂VDS.
vdsat: drain-source saturation voltage predicted by the compact model.
vth: threshold voltage at the current bias point.
id: drain current.
ibd: bulk-to-drain junction diode current.
ibs: bulk-to-source junction diode current.
gbd: small-signal conductance of the bulk-drain diode.
gbs: small-signal conductance of the bulk-source diode.
isub: substrate current.
igidl: gate-induced drain leakage current.
igisl: gate-induced source leakage current.
igs, igd, igb: gate-to-source, gate-to-drain, and gate-to-body leakage currents.
igcs, igcd: gate-to-channel-source-side and gate-to-channel-drain-side tunneling/leakage components.
vbs, vgs, vds: terminal bias voltages body-source, gate-source, and drain-source.

### Capacitances

These are the intrinsic small-signal capacitance matrix terms of the MOSFET.
cgg: gate charge sensitivity to gate voltage.
cgs: gate-to-source capacitance term.
cgd: gate-to-drain capacitance term.
cbg: body-to-gate capacitance term.
cbd: body-to-drain capacitance term.
cbs: body-to-source capacitance term.
cdg: drain-to-gate capacitance term.
cdd: drain-to-drain self-capacitance term.
cds: drain-to-source capacitance term.
csg: source-to-gate capacitance term.
csd: source-to-drain capacitance term.
css: source-to-source self-capacitance term.
cgb: gate-to-body capacitance term.
cdb: drain-to-body capacitance term.
csb: source-to-body capacitance term.
cbb: body-to-body self-capacitance term.
capbd: bulk-drain junction capacitance.
capbs: bulk-source junction capacitance.

### Charges

qg: gate charge.
qb: bulk/body charge.
qd: drain terminal charge.
qs: source terminal charge.
qinv: inversion-channel charge.
qdef: charge-deficit state variable used in the NQS formulation; when NQS is off it is usually zero or irrelevant.

### NQS/Dynamic Terms

gerg: gate-charge-related conductance term that appears in advanced dynamic/NQS modeling.
gtau: conductance associated with the NQS time constant T\tauT.
vgsteff: effective gate overdrive used internally by the model.
vdseff: effective drain-source voltage used internally by the model equations.

### Overlap/Effective Dimensions

cgso: gate-source overlap capacitance.
cgdo: gate-drain overlap capacitance.
cgbo: gate-body overlap capacitance.
weff: effective channel width after model corrections.
leff: effective channel length after model corrections.

The system 3601 is configured to generate a circuit representation 3606, which may be a circuit netlist or a graph. In this graph representation 3606, circuit components are represented as nodes and their electrical connections are represented as edges. The graph representation 3606 is formed by incorporating a feature list 3608 constructed for each circuit component. The feature list 3608, which forms a feature vector for each node in the graph, includes the extracted operating point data 3604. In some cases, the feature list 3608 also includes component-type information and physical properties, such as transistor width (w), length (l), and multiplier (m). For passive components such as resistors or capacitors, the operating point entries in the feature list 3608 may be set to zero, while their structural or physical parameters are retained. In some cases, the operating point data includes electro-physical state variables that reflect operating conditions of circuit components. In some cases, the operating point data may be normalized using a data-driven calibration procedure to handle values that span several orders of magnitude, making the system robust to outliers.

In some cases, for each node in the circuit graph, a fixed-length feature vector is constructed. An example of a feature vector is:

```
node_feature = [
  one_hot_component_type,
    l / norm_l,
    w / norm_w,
    m / norm_m,
    vth[0..K−1] / norm_vth,
    vds[0..K−1] / norm_vds,
    vgs[0..K−1] / norm_vgs,
    id[0..K−1] / norm_id,
  cgg[0,K−1] / norm_id,
  cgd[0,K−1]/norm_id,
  cgs[0,K−1]/norm_id
]
```

The graph representation 3606 is provided as an input to a graph processing layer 3610. The graph processing layer 3610 is configured to process the graph representation 3606 and generate a graph-level output. In some cases, the graph processing layer 3610 includes a plurality of graph convolutional network (GCN) layers, shown as GCN layer 1, GCN layer 2, and GCN layer 3. Each GCN layer produces progressively contextualized node representations by propagating information across the circuit topology, thereby incorporating and reasoning over both the circuit's structure and the device-level operating point features contained in the feature list 3608. The system is configured to be dynamic, such that after each simulation, the physics extraction module 3602 obtains new operating point data 3604, and the feature lists 3608 for the graph representation 3606 are updated. This ensures the graph reflects the current physical operating condition of the circuit for each optimization step.

In some cases, the circuit representation 3606 includes a graph schematic, which indicates the visual topology of electrical components and how they connect, whereby each node is an electrical component. This graph is processed by the AI-based system 3601 and provides topological context to the AI processing layers.

An output of the graph processing layer 3610 may be provided to an optional projection stage 3612. The projection stage 3612 is configured to convert the graph-level information, which may be of variable size, into a fixed-dimension vector suitable for combination with other data.

In parallel to the processing of the graph representation 3606, the system 3601 obtains raw observation data 3614. The raw observation data 3614 may include measured or simulated performance metrics of the circuit, such as gain or noise, and associated target values for those metrics. This raw observation data 3614 is processed by a metric processing network 3616. The metric processing network 3616, which May be implemented as a multilayer perceptron comprising an input layer, one or more hidden layers, and an output layer, encodes the performance-based information into a metric-level output, which is typically a fixed-length representation.

The system 3601 further comprises a fusion operator 3618, which in some cases may be a summation operator. The fusion operator 3618 is configured to combine the graph-level output from the graph processing layer 3610 (via the projection stage 3612) and the metric-level output from the metric processing network 3616. This combination produces a joint observation representation that advantageously incorporates both physics-informed graph features and performance metric features.

This joint observation representation is provided to a policy network 3620. The policy network 3620, which may also be a multilayer perceptron with an input layer, hidden layers, and an output layer, is configured to process the joint observation representation to generate control outputs corresponding to circuit design actions. The output of the policy network 3620 is an action vector 3622, which represents one or more optimization actions to be applied to the circuit design, such as sizing adjustments (e.g., changing transistor width) or component-value adjustments. By combining circuit topology, internal physical operating points, and performance metrics, the system 3601 enables physics-informed and topology-aware decision-making, leading to faster, more stable, and higher-quality circuit optimization.

In some cases, the AI-based system 3601 reduces training steps, which means less processing steps and lower compute resource usage.

In some embodiments, the architecture is configured to promote transferability across different circuit design tasks. For example, training performed on a first circuit may be leveraged to reduce training time or computational effort when optimizing a second circuit having a similar topology and component composition. Such transferability may enable reuse of learned representations, policies, or optimization parameters across related circuit instances.

In some cases, the physics extraction module contributes to improved sample efficiency by augmenting observations with simulator-derived physical information. In addition, the inclusion of physics-based features may further support transferability by anchoring learned representations in device-level physical behavior that is consistent across circuits of similar type.

In certain implementations, multiple circuit nodes may be grouped into a reduced set of representative nodes, referred to herein as group nodes. By way of example, a circuit graph comprising on the order of one hundred nodes may be abstracted into a smaller number of group nodes, such as three group nodes, where each group node represents a collection of circuit components.

The formation of group nodes may be based on prior knowledge, such as predefined libraries or known structural relationships, and/or based on automated techniques such as clustering. In some embodiments, clustering is used to aggregate nodes according to similarity, with a centroid or representative feature vector computed for each group. This leads to transferability and, therefore, less computing operations since an group of nodes can now be represented as a single node.

In some cases, the graph processing layer may facilitate transferability by operating on abstracted or reduced graph representations, thereby enabling learned policies, operating condition representations, or optimization parameters to be reused across different circuit instances. In some cases, reducing the number of graph nodes may also affect sample efficiency, potentially improving efficiency under certain conditions while not necessarily guaranteeing such improvement in all scenarios.

In some cases, the physics extraction module may enhance sample efficiency by enabling the learning system to reason about physical properties and physical states of circuit components. For example, physics-based information may indicate whether a transistor is operating in a desired region, such as saturation, or whether a component is operating outside an intended range. Such information provides additional context beyond performance metrics alone and may also contribute to improved transferability across circuits with similar physical characteristics.

In some cases, integrating operating points into node features transforms the GNN from a topology encoder into a physics-state encoder. Each node represents not only the component type and size, but also its instantaneous operating condition across the circuit's operating range. This enriched representation provides the AI-based system with direct access to the internal state variables that govern analog behavior, enabling more informed and physically consistent design computations.

In some cases, in contrast to systems that rely solely on performance metrics or that separately employ topology-based processing, the disclosed architecture combines a metrics-based observation pathway with a graph processing layer that incorporates physics-based information. This integrated approach enables joint consideration of circuit topology, physical operating conditions, and performance measurements within a unified optimization framework.

Various systems or processes have been described to provide examples of embodiments of the claimed subject matter. No such example embodiment described limits any claim and any claim may cover processes or systems that differ from those described. The claims are not limited to systems or processes having all the features of any one system or process described above or to features common to multiple or all the systems or processes described above. It is possible that a system or process described above is not an embodiment of any exclusive right granted by issuance of this patent application. Any subject matter described above and for which an exclusive right is not granted by issuance of this patent application may be the subject matter of another protective instrument, for example, a continuing patent application, and the applicants, inventors or owners do not intend to abandon, disclaim or dedicate to the public any such subject matter by its disclosure in this document.

For simplicity and clarity of illustration, reference numerals may be repeated among the figures to indicate corresponding or analogous elements. In addition, numerous specific details are set forth to provide a thorough understanding of the subject matter described herein. However, it will be understood by those of ordinary skill in the art that the subject matter described herein may be practiced without these specific details. In other instances, well-known methods, procedures, and components have not been described in detail so as not to obscure the subject matter described herein.

The terms “coupled” or “coupling” as used herein can have several different meanings depending in the context in which these terms are used. For example, the terms coupled or coupling can have a mechanical, electrical or communicative connotation. For example, as used herein, the terms coupled or coupling can indicate that two elements or devices are directly connected to one another or connected to one another through one or more intermediate elements or devices via an electrical element, electrical signal, or a mechanical element depending on the particular context. Furthermore, the term 12 “operatively coupled” may be used to indicate that an element or device can electrically, optically, or wirelessly send data to another element or device as well as receive data from another element or device.

As used herein, the wording “and/or” is intended to represent an inclusive-or. That is, “X and/or Y” is intended to mean X or Y or both, for example. As a further example, “X, Y, and/or Z” is intended to mean X or Y or Z or any combination thereof.

Terms of degree such as “substantially”, “about”, and “approximately” as used herein mean a reasonable amount of deviation of the modified term such that the result is not significantly changed. These terms of degree may also be construed as including a deviation of the modified term if this deviation would not negate the meaning of the term it modifies.

Any recitation of numerical ranges by endpoints herein includes all numbers and fractions subsumed within that range (e.g., 1 to 5 includes 1, 1.5, 2, 2.75, 3, 3.90, 4, and 5). It is also to be understood that all numbers and fractions thereof are presumed to be modified by the term “about” which means a variation of up to a certain amount of the number to which reference is being made if the result is not significantly changed.

Some elements herein may be identified by a part number, which is composed of a base number followed by an alphabetical or subscript-numerical suffix (e.g., 112a, or 112b). All elements with a common base number may be referred to collectively or generically using the base number without a suffix (e.g., 112).

The systems and methods described herein may be implemented as a combination of hardware or software. In some cases, the systems and methods described herein may be implemented, at least in part, by using one or more computer programs, executing on one or more programmable devices including at least one processing 6 element, and a data storage element (including volatile and non-volatile memory and/or storage elements). These systems may also have at least one input device (e.g. a pushbutton keyboard, mouse, a touchscreen, and the like), and at least one output device (e.g. a display screen, a printer, a wireless radio, and the like) depending on the nature of the device. Further, in some examples, one or more of the systems and methods described herein may be implemented in or as part of a distributed or cloud-based computing system having multiple computing components distributed across a computing network. For example, the distributed or cloud-based computing system may correspond to a private distributed or cloud-based computing cluster that is associated with an organization. Additionally, or alternatively, the distributed or cloud-based computing system be a publicly accessible, distributed or cloud-based computing cluster, such as a computing cluster maintained by Microsoft Azure™, Amazon Web Services™, Google Cloud™, or another third-party provider. In some instances, the distributed computing components of the distributed or cloud-based computing system may be configured to implement one or more parallelized, fault-tolerant distributed computing and analytical processes, such as processes provisioned by an Apache Spark™ distributed, cluster-computing framework or a Databricks™ analytical platform. Further, and in addition to the CPUs described herein, the distributed computing components may also include one or more graphics processing units (GPUs) capable of processing thousands of operations (e.g., vector operations) in a single clock cycle, and additionally, or alternatively, one or more tensor processing units (TPUs) capable of processing hundreds of thousands of operations (e.g., matrix operations) in a single clock cycle.

Some elements that are used to implement at least part of the systems, methods, and devices described herein may be implemented via software that is written in a high-level procedural language such as object-oriented programming language. Accordingly, the program code may be written in any suitable programming language such as Python or Java, for example. Alternatively, or in addition thereto, some of these elements implemented via software may be written in assembly language, machine language or firmware as needed. In either case, the language may be a compiled or interpreted language.

At least some of these software programs may be stored on a storage media (e.g., a computer readable medium such as, but not limited to, read-only memory, magnetic disk, optical disc) or a device that is readable by a general or special purpose programmable device. The software program code, when read by the programmable device, configures the programmable device to operate in a new, specific, and predefined manner to perform at least one of the methods described herein.

Furthermore, at least some of the programs associated with the systems and methods described herein may be capable of being distributed in a computer program product including a computer readable medium that bears computer usable instructions for one or more processors. The medium may be provided in various forms, including non-transitory forms such as, but not limited to, one or more diskettes, compact disks, tapes, chips, and magnetic and electronic storage. Alternatively, the medium may be transitory in nature such as, but not limited to, wire-line transmissions, satellite transmissions, internet transmissions (e.g., downloads), media, digital and analog signals, and the like. The computer usable instructions may also be in various formats, including compiled and non-compiled code.

While the above description provides examples of one or more processes or systems, it will be appreciated that other processes or systems may be within the scope of the accompanying claims.

To the extent any amendments, characterizations, or other assertions previously made (in this or in any related patent applications or patents, including any parent, sibling, or child) with respect to any art, prior or otherwise, could be construed as a disclaimer of any subject matter supported by the present disclosure of this application, Applicant hereby rescinds and retracts such disclaimer. Applicant also respectfully submits that any prior art previously considered in any related patent applications or patents, including any parent, sibling, or child, may need to be revisited.

What is claimed is:

1. A computing system for automatically modifying an electrical circuit, the computing system comprising: a memory storing instructions; and a processor operatively coupled to the memory, the processor configured by the instructions to: execute an iterative optimization process loop, the process loop comprising: (a) causing a simulation environment to simulate the electrical circuit using a current set of one or more controllable parameters to generate a corresponding set of performance metrics; (b) providing the set of performance metrics to an artificial intelligence (AI) agent, wherein the AI agent is configured to process a topological representation of the electrical circuit; (c) receiving, from the AI agent, a new set of the one or more controllable parameters, wherein the new set is generated by the AI agent based on the set of performance metrics and one or more target specification values; and (d) repeating steps (a) through (c) using the new set as the current set of the one or more controllable parameters for a subsequent iteration.

2. The computing system of claim 1, wherein the topological representation comprises a graph representation, wherein components of the electrical circuit correspond to nodes of the graph representation and connections between the components correspond to edges of the graph representation.

3. The computing system of claim 2, wherein the AI agent comprises a graph convolutional neural network (GCN) configured to process the graph representation.

4. The computing system of claim 1, wherein the AI agent is configured with a reinforcement learning (RL) framework to generate the new set of the one or more controllable parameters.

5. The computing system of claim 4, wherein the RL framework comprises an actor-critic architecture.

6. The computing system of claim 1, wherein the processor is further configured to generate the topological representation by at least: ingesting an image of a circuit diagram; using image recognition to extract a plurality of components and a plurality of connections that form the circuit diagram; and, generating a data file that comprises the topological representation, the data file processed by the AI agent.

7. The computing system of claim 1, wherein the process loop is repeated until a stop condition is detected, the stop condition comprising at least one of: a determination that the set of performance metrics meets or exceeds the one or more target specification values, or a determination that a series of consecutive sets of performance metrics has reached a steady state.

8. The computing system of claim 1, wherein the processor is further configured to display, via a graphical user interface, a visualization of the performance metrics generated during each iteration of the process loop.

9. A computing system for automatically modifying an electrical circuit, the computing system comprising a memory, a communication interface, and a processor operatively coupled to the memory and the communication interface;
the processor configured to:
obtain a data file representing the electrical circuit;
obtain one or more controllable parameters of the electrical circuit and one or more target specification values of the electrical circuit;
initiate a process loop comprising inputting the data file and an initial value set of the one or more controllable parameters into a simulation environment and obtain, from the simulation environment, an initial set of specification values resulting from 26 simulating the electrical circuit;
execute the process loop comprising:
input the data file, the initial set of specification values, and the one or more target specification values into an artificial intelligence (AI) agent, comprising a graph convolutional neural network with reinforcement learning, to obtain a new value set of the one or more controllable parameters; and
feedback the new value set of the one or more controllable parameters into the simulation environment, to continue the process loop, comprising generating another set of specification values resulting from simulating the electrical circuit using the new value set of the one or more controllable parameters, wherein the another set of specification values are inputted into the AI agent; and
repeat the process loop of the simulation environment and the AI agent, until a stop condition has been detected.

10. The computing system of claim 9, comprising an AI electrical simulation platform, the simulation environment and the AI agent; and wherein, the AI electrical simulation platform communicates with the simulation environment and with the AI agent via respective data connectors.

11. The computing system of claim 9, wherein the processor is configured to obtain the electrical circuit by at least: ingesting an image of a circuit diagram; using image recognition to extract a plurality of components and a plurality of connections that form the circuit diagram; and, generate the data file that comprises the plurality of components and the plurality of connections to represent the circuit diagram.

12. The computing system of claim 11, wherein the data file comprises a graph representation comprising a plurality of nodes representing the plurality of components.

13. The computing system of claim 9, wherein the processor is configured to display a graphical user interface that comprises a series of sets of specification values outputted by the simulation environment in real-time corresponding to each iteration of the process loop.

14. The computing system of claim 9, wherein the stop condition comprises a given iteration of a set of specification values matches or exceeds the one or more target specification values, or the stop condition comprises a series of consecutive sets of specification values has reached a steady state, or both.

15. An artificial intelligence-based system for modifying a circuit design, the system comprising:
a physics extraction module configured to obtain operating point data for a plurality of components of a circuit from a circuit simulator;
a graph processing layer configured to process a graph representation of the circuit to generate a graph-level output, wherein nodes of the graph representation correspond to the plurality of components and are associated with feature vectors comprising operating point data of the plurality of components;
a metric processing network configured to process performance metric data associated with the circuit to generate a metric-level output;
a fusion operator configured to combine the graph-level output and the metric-level output to produce a joint observation representation; and
a policy network configured to process the joint observation representation to generate an action vector corresponding to an optimization for the circuit design.

16. The system of claim 15, wherein the graph processing layer comprises one or more graph convolutional network (GCN) layers configured to propagate information across a topology of the circuit.

17. The system of claim 15, wherein the feature vectors associated with the nodes of the graph representation further comprise component-type information and physical property information for the plurality of components.

18. The system of claim 15, further comprising a projection stage configured to convert the graph-level output into a fixed-dimension vector before the graph-level output is combined by the fusion operator.

19. The system of claim 15, wherein the system is configured to update the feature vectors with new operating point data obtained by the physics extraction module after each simulation of the circuit.

20. The system of claim 15, wherein the operating point data is normalized based on a data-driven calibration procedure.
